(19) United States
(12) Patent Application Publication
(10) Pub. No.: US 2018/0180829 A1
(43) Pub. Date: Jun. 28, 2018

(54) MICROFABRICATED OPTICAL APPARATUS WITH FLEXIBLE ELECTRICAL CONNECTOR

(71) Applicant: Innovative Micro Technology, Goleta, CA (US)

(72) Inventor: Christopher S. GUDEMAN, Lompoc, CA (US)

(73) Assignee: Innovative Micro Technology, Goleta, CA (US)

(21) Appl. No.: 15/903,066

(22) Filed: Feb. 23, 2018

Related U.S. Application Data
(63) Continuation-in-part of application No. 15/272,481, filed on Sep. 22, 2016.

(51) Int. Cl. G02B 6/42; G02F 1/095; B81C 1/00; B81B 7/00; G02B 27/09; H01S 5/183; H01S 5/02; H01S 5/022; H04J 14/02; H04B 10/40

(52) U.S. Cl. CPC G02B 6/4284; G02F 1/0955; B81C 1/00301; B81B 7/0067; B81B 7/007; G02B 27/0955; H04B 10/40; H01S 5/021; H01S 5/02284; H01S 5/02288; H01S 5/02252; H01S 5/02292; H04J 14/02; H01S 5/18361

(57) ABSTRACT

A microfabricated optical apparatus that includes a light source driven by a waveform, wherein the waveform is delivered to the light source by at least one through silicon via. The microfabricated optical apparatus may also include a light-sensitive receiver which generates an electrical signal in response to an optical signal. An optical source may be attached to a carrier substrate with the TOSA by a flexible connector, in order to align the optical source before affixing it permanently.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to integrated circuit and microelectromechanical systems (MEMS) devices. More particularly, this invention relates to a microfabricated optical apparatus wherein vias are formed completely through the silicon substrates.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer.

One such device that may be manufactured using MEMS techniques is a microfabricated optical table. Microfabricated optical tables may include very small optical components which may be arranged on the surface of a substrate in a manner analogous to a macroscopic optical components mounted on a full sized optical bench. These microfabricated components may include light sources such as light emitting diodes (LED's) or semiconductor lasers, beam shaping structures such as lenses, turning mirrors and wavegiudes, and modulation devices such as Mach-Zehnder interferometers or Electro_Absorbtive Modulators. After fabrication, these devices may be enclosed with a lid wafer to protect them in an encapsulated device cavity. Some devices, such as infrared detectors and emitters, may require a vacuum environment, such that the device cavity may need to be hermetically sealed.

In order to control such a microfabricated elements, electrical access must be provided that allows power and signals to be transmitted to and from the elements. Previously, these signal lines were routed under the bond lines between the lid wafer and the device wafer. Because the enclosed elements may be delicate, the bondlines may be, for example, metal alloy bondlines that are activated at relatively low processing temperatures. However, the presence of the flat metal bondlines directly adjacent to potentially high frequency signal lines may cause unwanted capacitance in the structure, limiting its high speed performance.

Accordingly, encapsulated microfabricated high frequency optical structures have posed an unresolved problem.

### SUMMARY

A method is described which can be used to make microfabricated optical tables using conductive vias which extend through the thickness of the substrate material.

A feature of this process is that conductive vias may be formed in a relatively insulative surrounding material of the substrate. These vias may supply power and signals to/from the components inside a hermetically sealed device cavity. The signal and power lines may be delivered to the sealed device cavity with a through substrate via (TSV). The TSV may have a bonding pad on one side of the substrate, and a conductive line leading to the device within the device cavity. Accordingly, this architecture avoids the large capacitive losses that may occur with the under-bond routing of these electrical leads. These vias may be located at intervals in the bondline, and may be electrically coupled to a grounded plane. This may cause the bondline to be grounded at intervals, such that it does not participate, or interfere with, the operation of the TOSA/ROSA, as described further below.

The encapsulated components may include turning mirrors, optical rotators and isolators, light emitters and optical lenses. Using this architecture, the turning mirror may be a reflective surface formed on a surface of the lid wafer, or it may be a separate component formed on the device wafer surface.

Numerous devices can make use of the systems and methods disclosed herein. In particular, high speed, compact telephone or communications switching equipment may make use of this architecture. RF switches benefit from the reduced capacitive coupling that an insulative substrate can provide. High density vias formed in the insulative substrate increase the density of devices which can be formed on a substrate, thereby reducing cost to manufacture. Other sorts of substrates, for example, metal or semiconducting substrates may make use of an insulating layer to provide isolation between the conductive via and the surrounding substrate. The performance of such devices may also be improved, in terms of insertion loss, distortion and isolation figures of merit.

Accordingly, the microfabricated optical apparatus fabricated on a substrate, may include a light source driven by a signal, wherein the light source generates optical radiation, a beam shaping element, and a turning surface which redirects the beam of light, wherein the signal is delivered to the light source by at least one through silicon via (TSV) which extends through a thickness of the substrate. The systems and methods may include elements of wafer level packaging (WLP), wafer bonding, pick and place mechanisms, MEMS processes, methods, structures and actuators.

In another embodiment, the microfabricated optical apparatus may include an optical receiver as well as an optical transmitter. The receiver may be, for example, a photo-sensitive diode. The embodiment may also include two optical isolators, one to separate incoming from outgoing radiation. The incoming radiation may be directed onto the optical receiver through a beam shaping element such as a ball lens. Accordingly, in this embodiment, the microfabricated optical apparatus may be fabricated on a substrate, and may include a light source driven by a signal, wherein the light source generates optical radiation; a light detector which detects an amount of optical radiation, wherein the signal is delivered to the light source or taken from the optical detector by at least one through silicon via (TSV) which extends through a thickness of the substrate. Two such optical apparatuses may be disposed on either end of a fiber optic transmission line, allowing two-way communication across the fiber optic.

The method for fabricating an optical apparatus on a substrate may include forming a device cavity in a lid wafer, forming a through silicon via through the substrate, disposing a light source driven by a waveform which generates optical radiation on the substrate, and coupling the light source electrically to the through silicon via, disposing a beam shaping element on the substrate, disposing a turning surface which redirects the beam of light, and bonding the substrate to the lid wafer to encapsulate the optical apparatus in a hermetic device cavity.

In another embodiment, a flexible electrical connector may be used to provide power to activate the optical source or optical receiver. By having the optical device operational, the orientation of the optical device with respect to a waveguide may be adjusted to optimize the coupling between the optical device and the waveguide. These and other features and advantages are described in, or are apparent from, the following detailed description.

### BRIEF DESCRIPTION OF THE DRAWINGS

Various exemplary details are described with reference to the following figures, wherein:

FIG. 1 is a schematic, cross sectional illustration of a first embodiment of a microfabricated optical apparatus;

FIG. 2 is a schematic, cross sectional illustration of a second embodiment of a microfabricated optical apparatus;

FIG. 3 is a schematic, cross sectional illustration of a third embodiment of a microfabricated optical apparatus;

FIG. 4 is a schematic, cross sectional illustration of a fourth embodiment of a microfabricated optical apparatus;

FIG. 5 is a schematic, cross sectional illustration of a fifth embodiment of a microfabricated optical apparatus.

FIG. 6 is a schematic, cross sectional illustration of a sixth embodiment of a microfabricated optical apparatus with a plurality of light sources;

FIG. 7a is a schematic, plan view of a seventh embodiment of a microfabricated optical apparatus with a receiving unit as well as a transmitting unit; FIG. 7b is a schematic, plan view of a seventh embodiment of a microfabricated optical apparatus using two data channels on different wavelengths;

FIG. 8 is a schematic, plan view of an eighth embodiment of a microfabricated optical apparatus with multiple receiving units as well as multiple transmitting units;

FIG. 9a is a plan view of a substrate with multiple optical apparatuses fabricated thereon, wherein the bondline is grounded at intervals; FIG. 9b is a cross sectional view of a substrate with multiple optical apparatuses fabricated thereon, wherein the bondline is grounded at intervals.

FIG. 10 is a cross sectional view of a TOSA/ROSA structure encapsulated with a lid wafer which isolates the TOSA from the ROSA;

FIG. 11 is a 3-dimensional perspective view of a packaged TOSA/ROSA structure;

FIG. 12 is a perspective view of a first step in an attachment method using the edge of a semiconductor substrate;

FIG. 13 is a perspective view of a second step in the attachment method using the edge of a semiconductor substrate;

FIG. 14 is a perspective view of a third step in the attachment method using the edge of a semiconductor substrate;

FIG. 15 is a perspective view of a first step in the attachment method using a pocket in a semiconductor substrate;

FIG. 16 is a perspective view of a second step in the attachment method using a pocket in a semiconductor substrate;

FIG. 17 is a perspective view of a third step in the attachment method using a pocket in a semiconductor substrate;

FIG. 18 is an exemplary flowchart illustrating the attachment method; and

FIG. 19 is a plan view of a substrate with multiple optical apparatuses fabricated thereon.

It should be understood that the drawings are not necessarily to scale, and that like numbers may refer to like features.

### DETAILED DESCRIPTION

The systems and methods described herein may be particularly applicable to microfabricated optical tables, wherein small optical devices are formed on a substrate surface and enclosed with a lid wafer. The optical devices may include light sources such as light emitting diodes (LED's), beam shaping structures such as lenses and turning mirrors, and modulation devices such as Faraday rotators and optical isolators. After fabrication, these devices may be enclosed with a lid wafer to protect them in an encapsulated device cavity. Some devices, such as optical detectors and optical or laser emitters, may require a vacuum environment, such that the device cavity may need to be hermetically sealed. The signal and power lines may be delivered to the sealed device cavity with a through substrate via (TSV). The TSV may have a bonding pad on one side of the substrate, and a conductive line leading to the device within the device cavity.

Through substrate vias may be particularly convenient for MEMS devices, because they may allow electrical access to the encapsulated devices. Without such through holes, electrical access to the MEMS device may have to be gained by electrical leads routed under the lid wafer which is then hermetically sealed. It may be problematic, however, to achieve a hermetic seal over terrain that includes the electrical leads unless more complex and expensive processing steps are employed. This approach also makes radio-frequency applications of the device limited, as electromagnetic coupling will occur from the metallic bondline residing over the normally oriented leads.

The systems and methods described herein may be particularly applicable to encapsulated optical tables, such as an LED, shaping lens, rotator/isolator and turning mirror, all enclosed in the device cavity. This optical apparatus may in turn be mounted on another carrier substrate, wherein the carrier substrate has at least one waveguide formed therein. The optical apparatus may be attached to a source of power by a flexible electrical connector, which may allow alignment between the optical apparatus and the waveguide, as described further below.

One of the problems with the prior art devices is that the leads that drive the laser emitter are necessarily routed under the bond lines that bond the lid wafer to the device wafer. Accordingly, a large capacitive coupling may occur, with commensurately large losses especially at high frequencies. Although these devices may be smaller and lower cost than a TO-can packaging with ceramic carrier, the performance of the device may suffer from the aforementioned capacitive coupling, especially at higher frequencies.

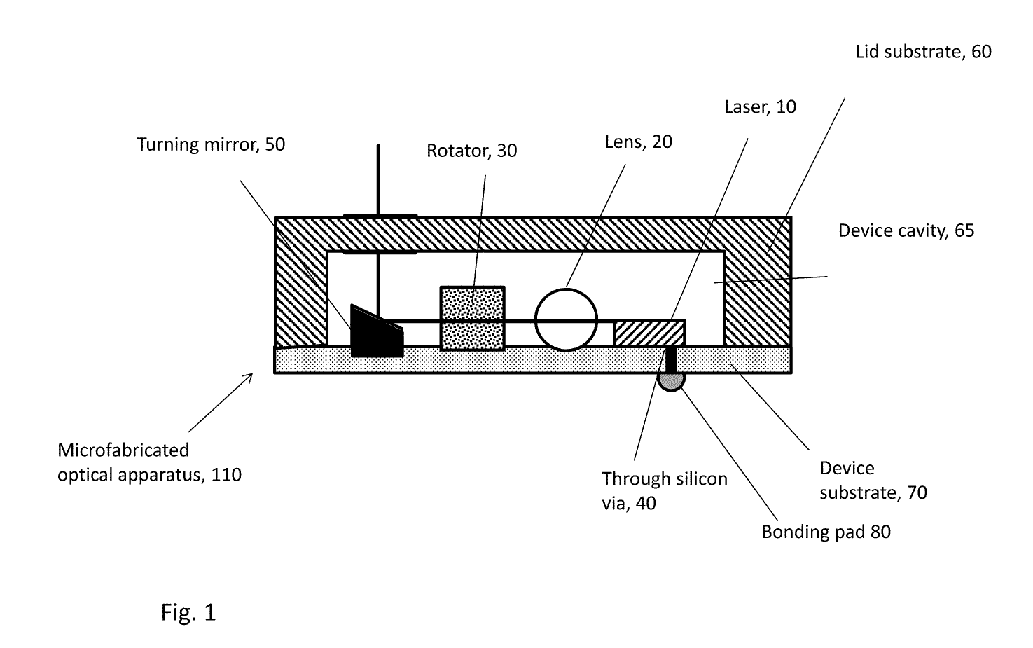

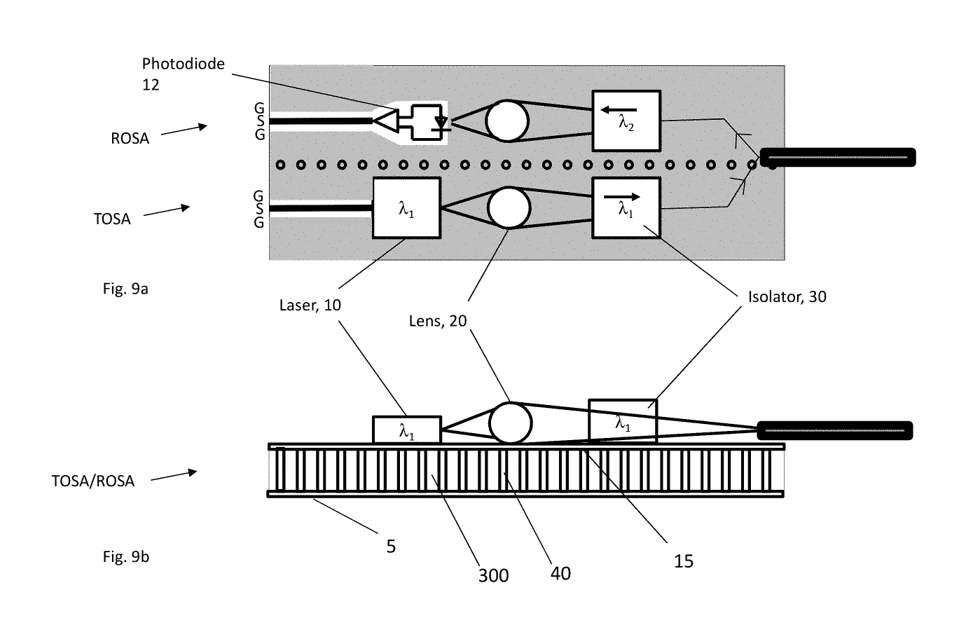

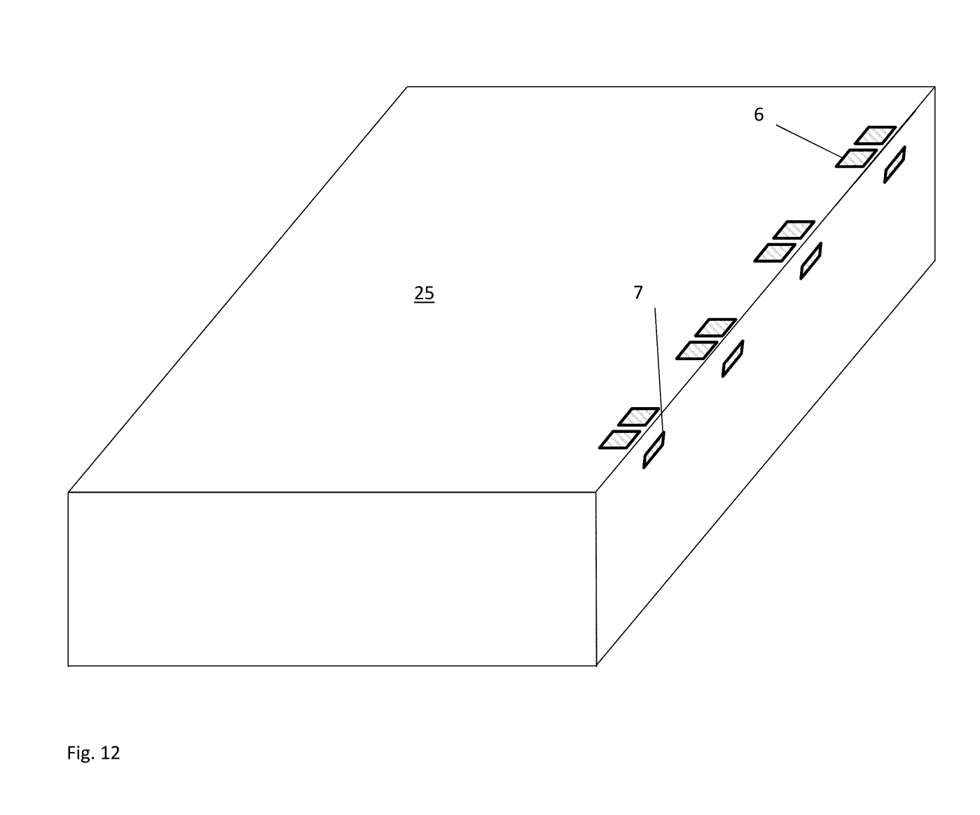

Exemplary embodiments of the novel optical apparatuses are illustrated in FIGS. 1-8. Embodiments of the novel optical apparatus that include a noise suppression scheme are shown in FIGS. 9-11. Embodiments of the optical apparatus that include this noise suppression as well as a flexible electrical connector are shown in FIG. 12-19.

FIG. 1 shows a first embodiment of the systems and methods disclosed here. In FIG. 1, there may be a laser light source 10 which produces a beam of light which may be shaped by a ball lens 20 and then through Faraday rotator 30. The beam of light then impinges on a turning surface 50 which redirects the light in a direction normal to the substrate, shown upward in FIG. 1. The light may pass through the lid substrate 60 which may encapsulate the aforementioned devices disposed on the device substrate 70. In FIG. 1, the turning surface is a turning mirror 50, which is a discrete structure, encapsulated in the device cavity along with the other components.

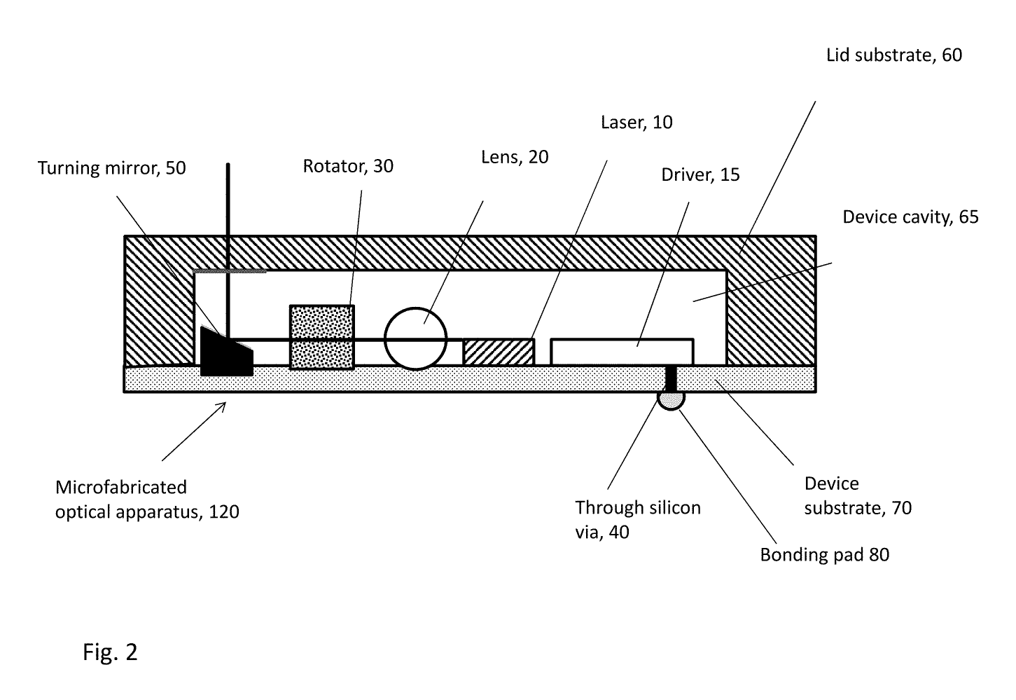

Suitable materials for the device substrate 70 and lid substrate 60 may be a metal or semiconductor such as silicon, or a ceramic or glass. The device cavity 65 may be etched into the lid wafer 60 using, for example, deep reactive ion etching (DRIE). The depth of the device cavity may be several hundred microns and have sufficient lateral extent to easily cover the components shown in FIGS. 2-8. Accordingly, the aforementioned components, including turning mirror 50, rotator 30, lens 20 and light source 10 may be disposed in the device cavity 65, such that the device cavity 65 encloses and encompasses the optical apparatus 110.

The laser 10 may be a light emitting laser diode for example, that can be driven by power and signal lines which are delivered to the laser 10 by one or more through silicon vias (TSVs) 40. These vias 40 are formed through the thickness of the device wafer 70. A number of references describe methods for making such through wafer vias 40. In the embodiment shown in FIG. 1, a discrete turning mirror 50 directs the beam of light from the laser 10, ball lens 20 and Faraday rotator 30 to a direction normal to the substrates. The beam of light may exit through the lid substrate 60.

This embodiment may make use of, for example, a single mode, distributed feedback (DFB) edge-emitting laser located within the device cavity, and thereby separated from the environment by a hermetic seal. The single mode, edge emitting diode may be capable of higher data rates than a multimode vertical cavity surface emitting lasers (VCSELs), such that this embodiment may have both performance and cost advantages. The DFB laser may be modulated directly by a signal or waveform fed to the DFB laser through the through silicon via, or it may be driven by a direct current (DC) electrical signal applied to the TSV. However, it should be understood that the light source 10 may be at least one of a light emitting diode, a laser diode, an edge emitting laser diode, a laser diode. and a vertical cavity surface emitting laser. The electrical access to the TSV 40 may be provided by a bonding pad 80, to which macroscopic electrical connections may be made. In the embodiments shown in FIG. 1, because the light is emitted through the lid substrate and thus on the obverse side compared to the electrical connections, this embodiment may be particularly convenient for coupling to a printed circuit board or thin film circuit.

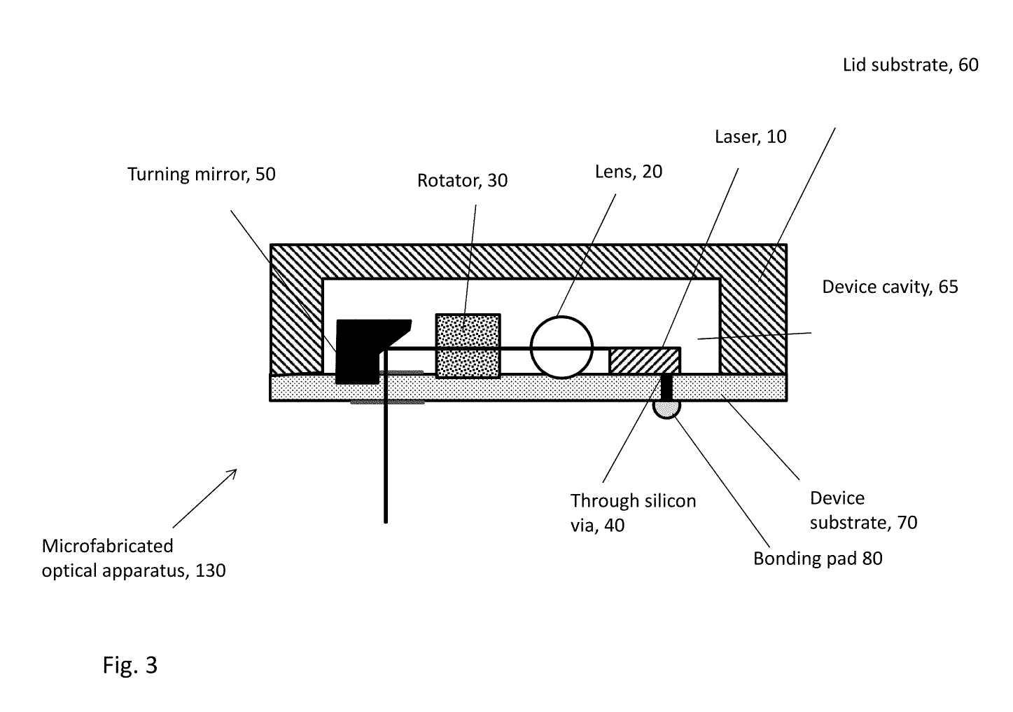

FIG. 2 shows another embodiment of the MEMS silicon optical apparatus. This second embodiment is similar to that shown in FIG. 1, except that in this embodiment, there is also a driver 15 that drives the laser 10 with a particular pattern or modulation that may represent data to be communicated over the optical link. Like the previous embodiment, there is once again a laser light source 10, which produces a beam of light which may be shaped by a ball lens 20, and then modulated by a Faraday rotator 30. The beam of light then impinges on a turning surface 50 which redirects the light in a direction normal to the substrate, shown as upward in FIG. 3. The light may pass through the lid substrate 60 which encapsulates the aforementioned devices disposed on the device substrate 70. In FIG. 2, the turning surface is a turning mirror 50, which is a discrete structure, encapsulated in the device cavity along with the other components. As in the previous embodiment, the laser is driven by through substrate vias 40, which may improve the high frequency characteristics of the device. The electrical access to the TSV may be provided by a bonding pad 80, to which macroscopic electrical connections may be made. In the embodiments shown in FIG. 2, because the light is emitted through the lid substrate and thus on the obverse side compared to the electrical connections, this embodiment may be particularly convenient for coupling to a printed circuit board or thin film circuit. In the embodiment shown in FIG. 2, the TSVs may conduct a direct current (DC) signal to the driver 15, which then modulates the signal to encode information thereon. Accordingly, this embodiment may include the power driver inside the hermetic package, and the close proximity of the compact device cavity provides for reduced power consumption. Therefore, the microfabricated optical apparatus may further comprise a device which modulates at least one of a frequency and an amplitude, to encode the optical radiation emitted from the light source with an information signal.

Otherwise, the embodiment shown in FIG. 2 may be similar to that shown in FIG. 1, and the turning mirror 50 may direct the optical radiation to exit the device cavity through a roof of the lid wafer, in a substantially parallel direction relative to the through silicon via.

FIG. 3 shows a third embodiment, wherein the turning mirror 50 directs the beam of light downward through the device substrate 70 rather than upward through the lid wafer 60. As in the previous embodiments, the laser may be driven by through substrate vias 40, which may improve the high frequency characteristics of the device. The output of this embodiment may be generally downward on the same side of the device as the electrical connections are made. Accordingly, in contrast to the embodiment shown in FIGS. 2 and 3, the optical apparatus in FIG. 3 has a turning mirror 50 which may bend the optical radiation to exit the device cavity through the device substrate 70, in a substantially parallel direction relative to the through silicon via.

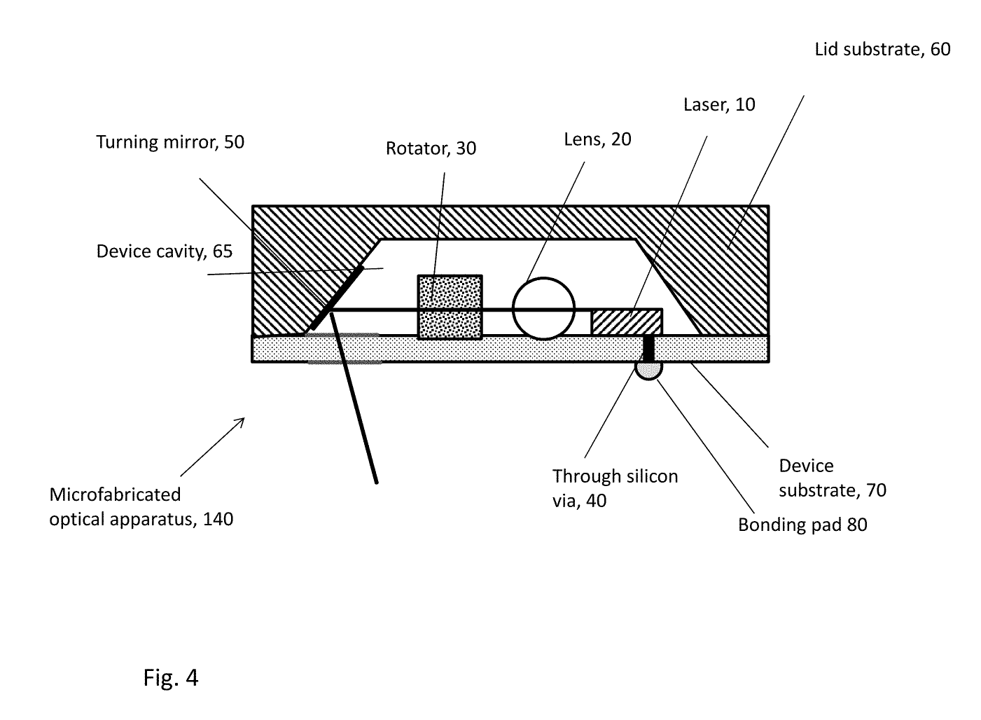

FIG. 4 shows a fourth embodiment of the MEMS silicon optical apparatus, wherein the turning surface 50′ is formed by a reflective surface on the lid wafer. This surface may be formed by anisotropic etching, followed by the deposition of a reflective coating on the lid wafer 60 surface. The reflective surface may be a thin film of gold (Au) or silver (Ag) or it may be a multilayer film with layer thicknesses designed to enhance reflectivity of the particular wavelength.

As in the previous embodiments, there is once again a laser light source 10, which produces a beam of light which may be shaped by a ball lens 20, and then modulated by a Faraday rotator 30. The beam of light then impinges on a turning surface 50′ which redirects the light through the substrate, shown as generally downward in FIG. 4. The light may pass through the device substrate 70 on which the aforementioned devices are fabricated, in a non-normal (with respect to the substrate). As in the previous embodiments, the laser may be driven by through substrate vias 40, which may improve the high frequency characteristics of the device. The device may have the advantage of simpler fabrication. Accordingly, in some embodiments, the microfabricated optical apparatus may generate optical radiation which exits the device cavity 65 through a sidewall of the device cavity 65 in the lid wafer 60, at an angle with respect to the through silicon via. In this case, the turning surface may be a reflective film deposited on a sidewall of the device cavity, wherein the sidewall is inclined with respect to a surface of the substrate by about 50 to 60 degrees. The turning surface may be a reflective film deposited on an inclined surface of an optical element located within the device cavity.

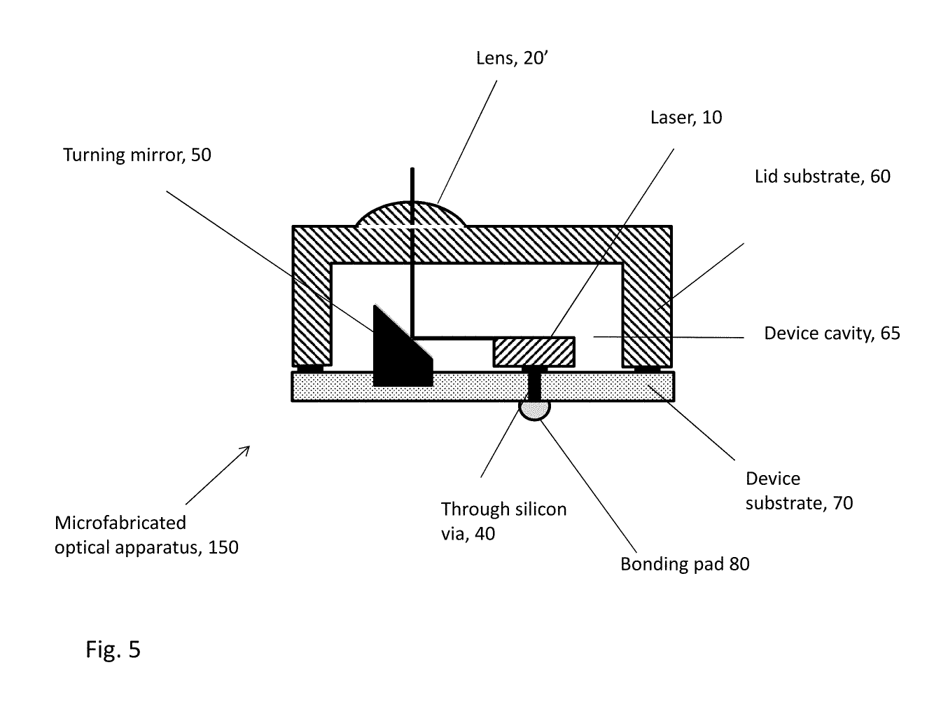

FIG. 5 shows a fifth embodiment of the MEMS silicon optical apparatus, wherein a laser 10 generates a beam of light which is redirected upward by turning mirror 50. This turning mirror 50 directs the light upward through the lid substrate 60. A feature lens 20′, may be formed on lid substrate 60 which can shape the beam of light as it passes therethrough. This embodiment is shown lacking some of the components described previously with other embodiments, such as the ball lens, Faraday rotator or isolator, and driver. It should be understood that these additional components may optionally be supplied with this embodiment as well. In FIG. 5, a horizontal line at the base of the lens 20′ may suggest that lens 20′ is a separate, distinct element. It should be understood that this horizontal line may be an artifact of the rendering of the illustration, and that lens 20′ may be formed from a monolithic piece of silicon as described below.

The feature lens 20′ may be formed using grey scale lithography, which makes use of a thick photoresist. “Thick resists” means, that the resist film thickness is much higher than the penetration depth of the exposure light. For standard positive resists and standard exposure wavelengths (g-, h-, i-line), this means a thickness of >5 μm. (Of course, if small wavelengths with a very low penetration depth such as 310 nm are used, even a 1 μm resist film will be “thick” in this context). Under these conditions, the resist film cannot be completely exposed towards the substrate. However, the resist may be bleached in the process as follows: In the beginning of the exposure, light only penetrates the upper 1-2 μm of the resist film. This part of the resist film bleaches, so with the exposure going on, light will be able to penetrate the first 2-3 μm of the film, and so on. As a consequence, the exposed (and developable) resist film thickness goes approx. linear with the exposure dose. The transition exposed/ unexposed is sufficiently sharp for reproducible greyscale lithography applications.

When the grayscale exposed resist is used in an etching process such as the one used to make lens 20′, the thin areas of the grayscale resist are removed early on, leading to relatively deeply etched features. The thicker areas of resist persist through the etching step, leading to shallowly etch features. Accordingly, the dome-shaped lens 20′ is produced by having thin portions of the grayscale resist cover the horizontal surface of the substrate, and the thickest areas over the top of the dome of the lens 20′

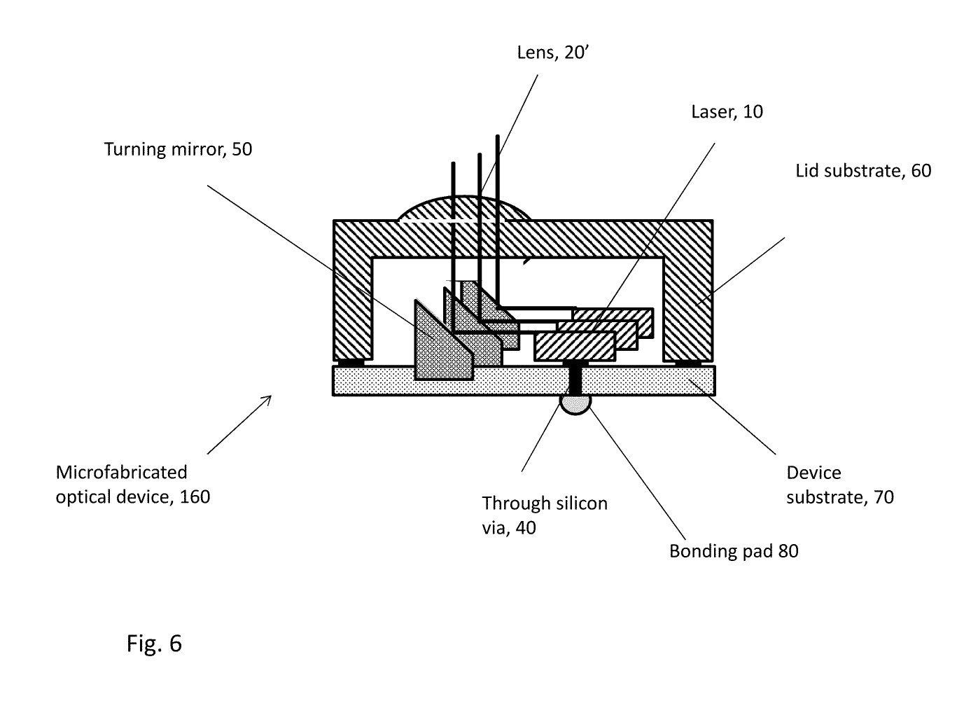

Grayscale lithography may be used to form a lens 20′ on either the outer surface or the inner surface of the roof of the device cavity lid substrate. A lens 20′ is shown on the outer surface in FIG. 6. Accordingly, the microfabricated optical apparatus may include a beam shaping element which is a lens formed in a roof of the device cavity.

As in the previous embodiments, there is once again a laser light source 10, which produces a beam of light which may be shaped by a ball lens 20, and then modulated by a Faraday rotator 30. The beam of light then impinges on a turning surface 50 which redirects the light in a direction normal to the substrate, shown as upward in FIG. 5 and downward in FIG. 3. The light may pass through the lid substrate 60 which may encapsulate the devices disposed on device substrate 60. As in the previous embodiments, the laser may be driven by through substrate vias 40, which may improve the high frequency characteristics of the device. The embodiment shown in FIG. 5 is shown lacking some of the components described previously with other embodiments, such as the ball lens, Faraday rotator or isolator, and driver. It should be understood that these additional components may optionally be supplied with this embodiment as well. The lens 20′ may serve to shape, focus or collimate the light emitted from light source 10 as driven through the through silicon via (TSV).

FIG. 6 shows a sixth embodiment of the MEMS optical apparatus, wherein a plurality of lasers 10 each generate a beam of light which is redirected by turning mirrors 50. These turning mirrors 50 may direct the light in the same or different directions as the other light sources. One or more feature lenses 20″, may be formed on lid substrate 60 which can shape the beams of light as they pass through. This embodiment is shown lacking some of the components described previously with other embodiments, such as the ball lens, Faraday rotator or isolator, and driver. It should be understood that these additional components may optionally be supplied with this embodiment as well. As shown in FIG. 6, the methods described here may be capable of manufacturing microfabricated optical apparatuses, wherein a plurality of light sources may be disposed in a single, compact, device cavity, along with the associated components. This plurality of light sources can be selected to operate at differing wavelengths, thus allowing data encoded on each wavelength to be transmitted together in a single optical fiber and then be separated from each other at the receiver end by use of a diffraction grating or discrete filters.

The through silicon vias (TSVs) 40 which are shown in each of FIGS. 2-7 may be made by a number of techniques. In one approach, blind via holes are etched into the front side of a silicon substrate, but not extending through the thickness, such that material remains on the backside of the substrate. An insulating layer, for example, silicon dioxide SiO₂ may then be grown on the bare silicon walls within the hole. A plating seed layer may then be deposited conformally in the hole. A conductive material such as copper, may then be plated into the hole. Finally, the remaining material may be removed from the backside of the substrate to expose the copper by, for example, grinding. The conductive copper may thereby extend through the thickness of the substrate 70. Additional details as to this method of making through silicon vias may be found in co-owned U.S. Pat. No. 7,233,048, which is incorporated by reference in its entirety.

Other methods may be used to form the vias, and some may be more appropriate for some substrate materials than others. These alternative methods may be found in, for example, U.S. patent application Ser. No. 11/482,944, U.S. Pat. No. 8,343,791, U.S. patent application Ser. No. 14/499,287 and United States Patent Application Ser. No. 13/987,871. Each of these documents in incorporated by reference in their entireties, and each is owned by the owner of the instant invention.

The other optical components may be obtained as discrete devices, and disposed on the fabrication substrate by pick and place machines, similar to those used in printed circuit board manufacture to place components. These discrete optical elements may be held in place by epoxy or glue. The light source 10 may require a conductive bonding material to maintain conductivity with the through silicon via. This conductive bonding material may be, for example, a relatively low temperature gold/tin alloy bond.

As mentioned previously, the lid substrate 60 may have a device cavity 65 etched therein using, for example, deep reactive ion etching (DRIE) or anisotropic etching. Anisotropic etching tends to form sidewalls with a 56 degree slope with respect to vertical, whereas DRIE tends to make very sharp, very vertical features. Anisotropic etching may be used on the embodiment shown in FIG. 4, whereas DRIE may be used in the embodiments shown in FIGS. 1-3 and 5-6. The 56 degree sidewall angle may be convenient for fabricating a reflective surface in order to direct the radiation out of the cavity.

After fabrication of the lid substrate 60 and placement of the optical elements within the perimeter of the device cavity, the lid substrate 60 may be bonded to the silicon device substrate 70. The bonding material may be, for example, a low temperature metal alloy bond such as gold/indium, which is formed at about 156 centigrade. Additional details as to methods for bonding with a gold and indium alloy may be found in U.S. Pat. No. 7,569,926, incorporated by reference in its entirety.

In modern data centers, optical fibers are used to interconnect the thousands of server computers that are racked together side by side. Because the data centers have grown and the number of servers has increased, the weight and girth of the fibers has become a significant problem during data center construction. Thus it is desirable to reduce the number of fibers. We describe here a method to carry two directional optical traffic down each fiber, using an embodiment of a microfabricated optical apparatus. This reduces the number of fibers in half.

In fiber-optic communications, wavelength-division multiplexing (WDM) is a technology which multiplexes a number of optical carrier signals onto a single optical fiber by using different wavelengths (i.e., colors) of laser light, thus multiplying the fiber's capacity. WDM systems are divided into different wavelength patterns, coarse (CWDM) and dense (DWDM).

Accordingly, both Coarse WDM (CWDM) and Dense WDM (DWDM) are currently used to increase the data rate down a given fiber. These methods rely on launching independently modulated optical signals at several wavelengths into each fiber. Each wavelength is generated by a separate laser. This optical energy is modulated in one of several methods to encode the data that is to be transmitted. These individual wavelength are combined into a single beam in an optical multiplexer and then launched into the long optical fiber that interconnects the servers. At the other end of each fiber, the light is disperse using a grating and each of the now separated wavelengths is detected and demodulated.

Whereas this method increases the throughput of each fiber, the data in each fiber travels in only one direction. Bi-direction communication between servers is required, so CWDM and DWDM require that pairs of fibers be used.

The method described here enables bi-directional communication on a single fiber. This can be implemented in a low cost application, which might have only one laser, or in a higher cost system that employs CWDM or DWDM. This concept includes a Transmit Optical Sub-Assembly (TOSA) and a Receive Optical Sub-Assembly (ROSA), which in combination are referred to as a microfabricated TOSA/ROSA apparatus. The TOSA/ROSA apparatus may be micro-fabricated on a single substrate, known as a Silicon Optical Bench (SiOB). The TOSA portion may use an edge emitting laser, a collimating ball lens, and an optical isolator, for example. The ROSA portion may use a second optical isolator (oriented in the opposite direction), a second collimating ball lens, and a photodiode (PD) as the optical detector, for example. An optical waveguide is fabricated on the SiOB that a) routes the laser light into the external optical fiber and b) routes the oppositely propagating light from the optical fiber to the PD. One each of these SiOBs is attached at the each end of the optical fiber.

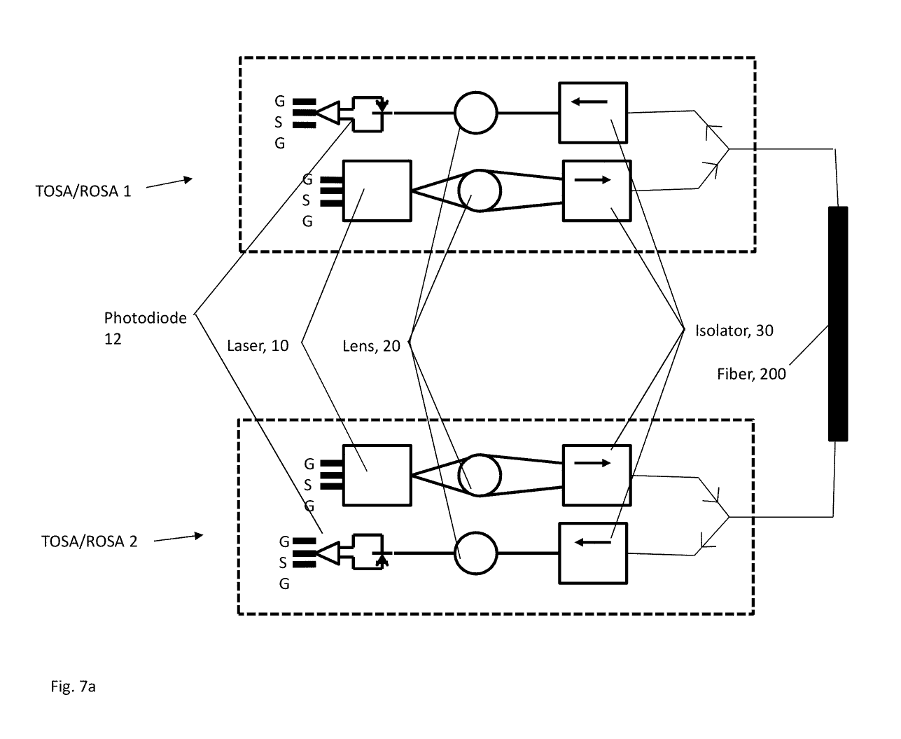

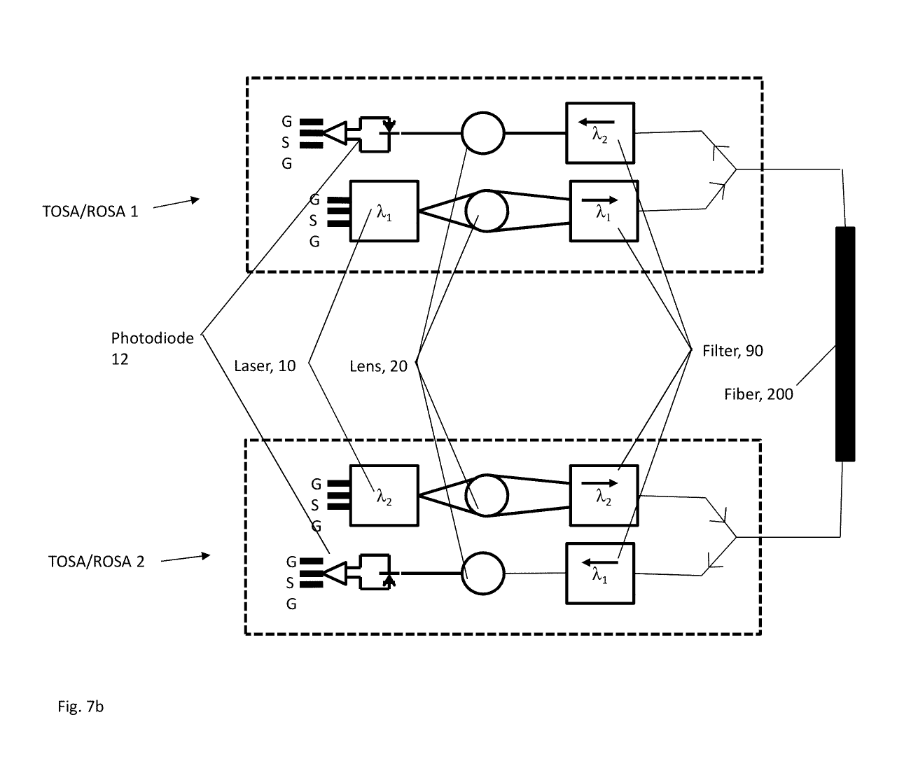

FIG. 7a is a simplified schematic diagram of two microfabricated optical apparatuses, TOSA/ROSA 1 and TOSA/ROSA 2. Both TOSA/ROSA 1 and TOSA/ROSA 2 have both transmit and receive capabilities but uses the microfabricated architecture described above with respect to FIGS. 1-7. As in the previous embodiments, there is once again a laser optical source 10, which produces a beam of light which may be shaped by a ball lens 20, and transmitted through an optical isolator (or Faraday rotator) 30. However, in contrast to the previous embodiments, there are now two ball lenses and two optical isolators in each module TOSA/ROSA 1 and TOSA/ROSA 2. In addition to these components, there is also an optical source 10 as well as an optical detector 12. These components may all be disposed within a device cavity between two substrates, a lid wafer and a device wafer, and form a TOSA/ROSA module. Both substrates may be semiconductor substrates such as silicon, or they may be glass, metal or ceramic.

The optical source 10 may be a light emitting diode, a laser diode, an edge emitting laser diode, a laser diode, or a vertical cavity surface emitting laser, for example. The optical detector 12 may be a photosensitive device such as a photodiode, a photomultiplier, or a charge-coupled device, for example. Accordingly, each TOSA/ROSA module 1, 2 can both generate optical radiation and detect optical radiation. Two such modules may be disposed on an optical fiber cable 200, at either end, as shown in FIG. 7a.

A plurality of through substrate vias (TSVs) may be formed in the device substrate as described above. The through substrate vias may be coupled to the optical source, providing the signal to be encoded by the optical source. Another of the pluralitys of TSVs may be coupled to the optical detector 12, carrying the signal generated by the detector in response to impinging light. A waveguide such as a strip line, co-axial cable or co-planar waveguide may be attached to the appropriate respective vias to provide ground (“G”), signal (“S”), and ground (“G”) to the microfabricated optical apparatus TOSA/ROSA 1 and TOSA/ROSA 2.

Accordingly, a microfabricated optical apparatus may be fabricated on a substrate, and include a optical source driven by a first signal, wherein the light source generates optical radiation, and an optical detector which generates a second signal based on an amount of optical radiation striking the optical detector, wherein the first and second signals are delivered to the optical source or taken from the optical detector by at least one through silicon via (TSV) which extends through a thickness of the substrate.

Beginning with TOSA/ROSA 1, an optical signal may be generated by optical source 10 and shaped by the beam shaping element, here a ball lens 20. The beam may pass through an optical isolator 30 and enter the fiber optic cable 200. The signal will exit the other end of fiber optic cable 200 and enter TOSAROSA 2. The beam may pass through an optical isolator 30 and beam shaping element 20 which may collimate the beam. The beam then impinges upon the optical detector 12. This constitutes the unidirectional communication, as shown by the arrowheads in FIG. 7a.

Bi-directional communication may occur in reverse, originating in TOSA/ROSA 2. Once again, an optical signal may be generated by optical source 10 in TOSA/ROSA 2, and shaped by the beam shaping element, ball lens 20 in TOSA/ROSA 2. The beam may pass through an optical isolator 30 and enter the fiber optic cable 200. The signal will exit the other end of fiber optic cable 200 and enter TOSA/ROSA 1. The beam may pass through an optical isolator 30 and beam shaping element 20 which may collimate the beam in TOSA/ROSA 1. The beam then impinges upon the optical detector 12. This constitutes the bi-directional communication.

Accordingly, bi-directional communication is enabled by the microfabricated TOSA/ROSA1, 2 as shown in FIG. 7a. The through substrate vias allow very compact packaging with a reduced level of noise, loss and inductive coupling at high frequencies.

FIG. 7b is a simplified schematic diagram of another embodiment of two microfabricated optical apparatuses, TOSA/ROSA 1 and TOSA/ROSA 2. Both TOSA/ROSA 1 and TOSA/ROSA 2 have both transmit and receive capabilities but use the microfabricated architecture described above with respect to FIGS. 1-7. As in the previous embodiments, there is once again laser optical sources 10, which produce a beam of light which may be shaped by a ball lens 20, and transmitted through an optical bandpass filter 90. The first laser source 10 in TOSAROSA 1 generates an optical signal at a wavelength λ1. Another laser source 10 in TOSAROSA 2 generates an optical signal at a wavelength λ2. As before, the radiation may be shaped by lenses 20. The two wavelengths constitute separate channels which can be encoded and multiplexed on the generating end, and demultiplexed and decoded on the receiving end. Accordingly, λ1 travels from TOSAROSA 1 down the fiber 200 to TOSAROSA 2. Wavelength λ2 travels in reverse from TOSAROSA 2 to TOSAROSA 1. The wavelengths can be separated by a Fabry-Perot filter, etalon or other optical bandpass filter 90. By superposition, the wavelengths can travel through the same fiber 200 and the same time, then be received and separated in order to decode the signal. This concept can be extended to a plurality of wavelengths and optical sources, greatly increasing the data rate of a given fiber optic channel.

Accordingly, as depicted in FIG. 7b, the microfabricated optical apparatus may comprise a plurality of optical sources, wherein a first optical source outputs a first wavelength, and a second optical source outputs a second wavelength, wherein the first wavelength and the second wavelength allow bi-directional communication in a single optical fiber.

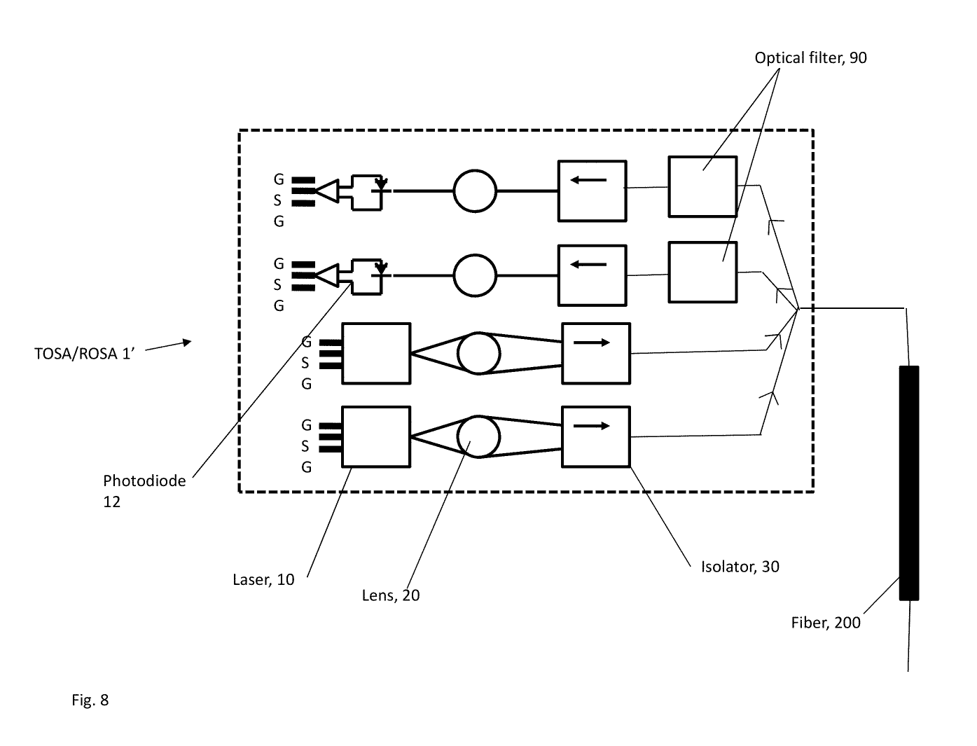

The features described previously with respect to FIGS. 2-7 may also be applied to the embodiment illustrated in FIGS. 8a and 8b. In particular, the microfabricated optical apparatus may further include a lid wafer with a device cavity formed therein, wherein the device cavity encapsulates the optical apparatus. The device cavity may encapsulate a plurality of light sources and a plurality of optical detectors. The output from the plurality of light sources may be combined in an optical multiplexer.

The signal may be a direct current electrical signal which is applied to the through silicon via. The apparatus may also include a device which modulates at least one of a frequency and an amplitude, to encode the optical radiation emitted from the light source with an information signal, and at least one optical isolator also disposed within the device cavity. The optical source may be at least one of a light emitting diode, a laser diode, an edge emitting diode, a laser diode. and a vertical cavity surface emitting laser. The optical detector may be a photodiode.

FIG. 8 is a simplified schematic diagram of another embodiment if a microfabricated optical apparatus TOSAROSA 1′ which may also have both transmit and receive capabilities as the embodiment shown in FIGS. 8a and 8b. However, in this embodiment, each TOSAROSA 1′ has a plurality of optical sources 10 and a plurality of optical detectors 12. Nonetheless, TOSA/ROSA 1′ may still use the microfabricated architecture described above with respect to FIGS. 1-8. As in the previous embodiments, there is once again a laser light source 10, which produces a beam of light which may be shaped by a ball lens 20, and is transmitted through an optical isolator (or Faraday rotator) 30. In contrast to the previous embodiments, there are now a plurality of such optical sources 10 and optical detectors 12 in TOSA/ROSA 1′.

This embodiment may be used in applications requiring multiple wavelengths encoding multiple data streams, such as CWDM and DWDM, mentioned above. The modulated signal may be fed to the plurality of optical sources 10 using the through substrate vias shown and described in the previous figures. The output of each of the sources may be injected into an fiber optic cable by a multilplexer, which may simply be the junction shown in FIG. 8.

As before, the optical isolator keeps reflections from entering the device cavity, and the ball lens 20 may shape the optical beam.

On the receiving end, the multi-wavelength signal may exit the fiber optic cable 200 and enter TOSAROSA 1′. The light may be split along different paths, and the optical isolators again prevents radiation traveling backwards through any portion of the system. Radiation passing to the (upper) receiving branch travels through a filter, 90, which separates the different wavelengths of light. Other separation mechanisms such as a rotatable grating or prism may also be used. Each wavelength may then impinge on one of the plurality of detectors.

Accordingly, optical radiation may enter and exit the device cavity through a fiber optic cable. The output from the fiber optic cable may be separated and delivered to the plurality of optical detectors. The apparatus may perform at least one of Coarse Wavelength Divisional Multiplexing (CWDM) and Dense Wavelength Divisional Multiplexing (DWDM), as described above.

It should be understood that a second TOSA/ROSA similar or identical to TOSA/ROSA 1′ may be disposed on the other end of fiber optic cable 200, as was shown and described with respect to FIG. 7a.

Alternatively, in another embodiment, the bi-directional transmission may use at least two different wavelengths. The wavelengths may be produced by the plurality of optical sources 10 putting out different specific wavelengths. The wavelengths may be separated at detection by an optical band-pass filter 90, such as an etalon or a Fabry-Perot filter. These separation devices may provide better isolation between the transmit and receive channels. And as mentioned, a first optical source may output a first wavelength, and a second optical source may output a second wavelength, wherein the first wavelength and the second wavelength allow bi-directional communication in a single optical fiber.

The embodiments illustrated in FIGS. 2-9 and described above have a number of advantages from a manufacturing perspective. They may be tested in a manufacturing environment with a conventional wafer probe to cull damaged or nonfunctional die. The design is capable of very high yield in a microfabrication production environment. They each allow integration of multiple lasers and detectors in a single device cavity, as was illustrated in FIGS. 7 and 9.

One technical difficulty of the structure shown in FIG. 8 may be feedthrough of the generated signal noise from the source 10 to the detector 12. Accordingly, a large noise source may be collocated in the package with the detector 12. What follows is an approach which may diminish the cross talk between the optical source 10 and the optical detector 12, and thus reduce the noise level and improve the overall performance of the device, a TOSA/ROSA.

We describe here a method that employs through substrate vias (TSVs) to frustrate the standing waves that may be formed in the package. Often, a metal layer which is electrically floating may form an antenna that can absorb and re-radiate the signal from the optical source. This reradiated signal may be detected by the optical detector 12 and constitute a major noise source for the detector 12, as the signal is fed through from the optical source 10 to the optical detector 12. Feedthrough may also occur directly from source 10 to detector 12 by radiating through space. Accordingly, it may be important to the performance of the device to inhibit the coupling between the source 10 and the detector 12. The method described here may form an effective and convenient shield for the optical detector 12, by grounding the metal planes in the structure that would otherwise act like an antenna.

In one embodiment, there may be a lower metal ground plane 5 on one surface, and a metal upper layer 20 with patterned traces on the other. The upper metal layer 20 may be deposited on at least one side of the substrate and covering a significant portion of the exposed area of the substrate. The upper metal layer 20 may also be electrically coupled to a ground plane on the obverse side of the substrate by the plurality of through substrate vias (TSVs)

Of course, the designation “upper” and “lower” is arbitrary, and meant only to indicate that one layer is on one side of a planar substrate, and the other layer is on the obverse side. A “covering a significant portion of the exposed area” may be understood to mean more than one-half of the total area of the surface of the substrate is covered with the metal of the upper metal layer 20.

The metal traces in the upper layer 20 may route electrical signals from a TSV to the TOSA/ROSA, and the lower layer may be a ground plane 5, held at ground potential with respect to the other voltages within the device. Some TSVs may handle the signals being delivered to the optical source 10 or taken from the detector 12, but others may provide the shielding function by grounding the metal upper layer through the TSVs, as described further below.

TSVs 40 may be formed at intervals in a TSV substrate, electrically coupling an metal upper layer 20 to the lower ground plane 5. The interval between the vias may be chosen according to the radiation being handled by the device, such that the radiation modes cannot be supported by the structure. As a result, the upper metal layer 20 may not interfere with the handling of the signals at their characteristic frequency, by coupling the transmitted signal to the signal detector 12.

More generally, a microfabricated structure is disclosed which supports signals having a characteristic wavelength of □ (which corresponds to a characteristic frequency □ of between about c/(□*□) and c/(10*□*□), where c is the speed of light and epsilon is the dielectric constant of the material). The structure may include a metallic layer such as a bond line or a metal trace layer, and a ground plane 5 which may be held at ground potential relative to the other metal layer. A plurality of through wafer vias may extend through the substrate, and define conductive paths between the ground plane 5 and the metal layer 20. The through wafer vias 40 may be disposed at intervals of between about 2□ and □/10. A method for fabricating this structure is also disclosed, and may include disposing an optical source driven by a first signal with a characteristic frequency of □ on a substrate, wherein the optical source generates optical radiation, disposing an optical detector on the substrate, which generates a second signal based on an amount of optical radiation striking the optical detector, wherein the first and second signals are delivered to the optical source or taken from the optical detector by a plurality of through silicon vias (TSV) which extend through a thickness of the substrate. The method may then further include forming a plurality of through wafer vias extending through at least one of a first substrate and a second substrate, that define a conductive path between a ground plane and a metallic bonding material, wherein the through substrate vias are disposed at intervals of between about c/(□*□) and c/(10*□*□), where c is the speed of light and epsilon is the dielectric constant of the substrate, and depositing an upper metal trace material on the substrate and electrically coupling the upper metal trace material to a ground plane by the plurality of through substrate vias (TSVs). Finally, the method may include forming the ground plane which is held at ground potential relative to the wafer bonding material.

Because the metal layer can no longer support the modes of the signal, the metal layer no longer interferes, by absorption and/or re-radiation, of the RF signal.

In this structure, there may be a ground plane 5 on one surface, which is a very low resistivity film such as Au or Al and is grounded to external circuitry in several places. This film may be 0.5-3.0 um in thickness, and is typically about 1 micron thick. The upper metal layer 20 is also typically Au, with a thickness of between 0.5-3.0 um. Rather than gold, however, the upper and lower layers may alternatively comprise aluminum, platinum, copper or silver, a noble metal, and a metal alloy, for example, and may again be about 1 micron thick. Some metal materials may need to be passivated, such as with a metal oxide layer, to avoid oxidation of the entire metal material.

In the figures that follow, 5 may be a ground plane, 10 may be a substrate, 40 may be one of a plurality of TSVs, 20 may be an upper metal layer which may have electrical traces formed therein, 50 may be a lid substrate.

Numerous ways for depositing a conductive material into a through hole or blind hole may be found in the literature and are known to those skilled in the art for making the through substrate vias 40. Several such methods are described briefly below.

Long, narrow vias 40 are often created by plating a conductive material into a blind hole formed in a substrate. Such a hole may be created in a substrate by, for example, a directional material removal process such as reactive ion etching (RIE). A seed layer may then be deposited conformally over the etched surface, to provide a conductive seed layer to attract the plating material from a plating bath. The hole may then be filled by plating onto the seed layer with a conductive material. Subsequently, the blind end wall of the hole may be removed by etching, sawing or grinding, for example, which may create a via that extends through the thickness of the substrate.

Another known method for making vias 40 is to use an anisotropic etch to form the holes with sloping sidewalls, and to deposit the conductive seed layer material on the sloped walls of the holes. However, this method often results in conductive seed layer material having non-uniform thickness, and the heat conduction in the thin deposited layer is relatively poor. The aspect ratio must also remain near 1:2 (width=2×depth), further limiting the density of the vias. In either case, the deposited layer may be used as a seed layer for the deposition of the conductive filler material by electrochemical plating deposition onto the seed layer. Then, as before, the blind end wall of the hole may be removed to create a via that extends through the substrate.

In one embodiment, the substrate 10 may be a portion of a silicon-oninsulator (SOI) substrate. The vias 40 may be formed through the thickness of the device layer, extending to the buried oxide by deep reactive ion etching (DRIE). The handle layer may now be removed to complete the backside processing. In another embodiment, a regular, monolithic silicon substrate may be used. In this case, the via may be formed as a blind hole partially through the substrate from the frontside. The backside may subsequently be ground or etched away. In other embodiments, the substrate 10 may be metal, glass, ceramic or sapphire for example. More generally, the substrate 10 may be any metal or metal alloy with at least one component of the alloy chosen from column II or III of the periodic table and another component chosen from column V or VI. Exemplary materials include gallium arsenide (GaAs), gallium nitride (GaN), aluminum nitride (AlN), indium arsenide (InAs), and indium phosphide (InP), among many others that can make use of this structure and method.

Other methods for forming electrical vias may be found in U.S. Pat. Nos. 7,233,048 and 8,343,791 and U.S. patent Application Ser. No. 13/987,871 and 14/499,287. Each of these patents and patent applications are incorporated by reference in their entireties.

In FIG. 9a, a ground plane 5 is disposed adjacent to a first substrate 300 which has a upper metal layer 15 which delivers signals and voltages to the components in the TOSA/ROSA as described above. The upper metal layer 15 may be a uniformly deposited layer of a conductor such as copper or gold, for example, which may be patterned to form metal traces. The upper metal layer 20 may be patterned by covering portions of upper metal layer 15 with a patterned photoresist coating and then etching or milling the exposed areas of upper metal layer 15, for example.

A plurality of through substrate vias 40 may be formed in the first substrate 300. These vias 40 may, of course, be filled with a conductive material as described above, and therefore constitute a conductive path between the ground plane 5 and the upper metal layer 15. Accordingly, the through substrate vias 40 effectively ground the upper metal layer 15 at various intervals around the upper metal layer 15. The intervals between the TSVs 40 are in general a fraction of the characteristic wavelength of the signal, for example, between about λ and λ/10. If considered in terms of a characteristic frequency v, the through wafer vias 40 may be disposed at intervals of between about c/(v*ϵ) and c/(10*v*ϵ), where c is the speed of light and epsilon is the dielectric constant of the material.

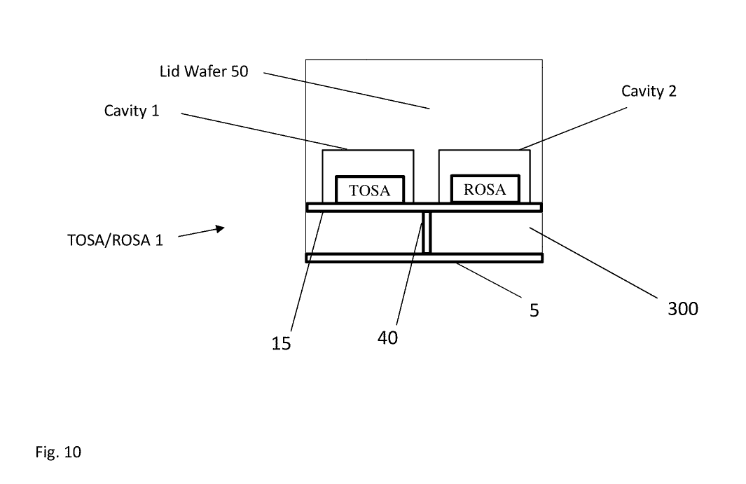

The architecture shown in FIGS. 10a and 10b and described above may effectively suppress signals at the operating frequency of the switch, thereby improving noise, loss and overall performance of the device. Even better isolation may be accomplished by packaging the TOSA/ROSA in a lid wafer with a pair of device cavities which encapsulate the TOSA portion separately from the ROSA portion, as described next.

FIG. 10 depicts a two-cavity lid wafer 50. Dual cavity lid wafer 50 may have a first cavity 1 and a second cavity 2. The cavities 1 and 2 may be formed by, for example, anisotropic etching. First cavity 1 may encapsulate the TOSA and second cavity 2 may encapsulate the ROSA. The lid wafer 50 may be bonded to another substrate 300 by a bonding material 15 on all contacting edges, using for example a gold compression bond or a metal alloy bond. In FIG. 10, the upper metal layer 15 may also be the bonding material which bonds lid wafer 50 to the substrate 300. The substrate material remaining between the first cavity 1 and the second cavity 2 may inhibit, to an extent, the transmission of the signal from the optical source 10 in the TOSA to the optical detector, 12 in the ROSA. However, much more effective cross talk suppression may be gained using the grounded through substrate vias (TSVs) as described below.

As mentioned, the first substrate 300 may be bonded to the lid substrate 50 with a metallic adhesive bonding material 51, for example. The bond seal may be made when the two wafers are bonded together using the malleable metal, such as Au, on each wafer. These two layers can be compressed together to form a thermo-compression bond or they can be soldered together by depositing a metal, for instance In or Sn, that readily alloys with a gold metal to form an alloy bond when a thermal cycle is applied to create the alloy. In any case, the metal layer 15 may be the bondline that adheres the two cavity lid wafer 50 to the substrate 300.

This metal bondline 15 may be grounded at intervals as described above, so that it is no longer electrically floating. As a result, the bondline may no longer act as a receiver or antenna for RF radiation at the characteristic frequency of the RF signal, and thus interfere with the functioning of the device. To this end, TSVs 40 may then be formed at intervals in the substrate 300, electrically coupling the metal layer 15 to the ground plane 5 as described above.

Accordingly, the TSVs 40 may exist in a periphery surrounding cavity 1 and cavity 2, as well as in the area between cavity 1 and cavity 2. The TSVs 40 may be located randomly throughout these structures or they may be located primarily in the areas described, and especially in the median areas between the TOSA and the ROSA. But in any case, the interval between the TSVs 40 is typically less that ¼ of the wavelength of the signal in the material. Accordingly, FIG. 10 may illustrate the packaged TOSAROSA 1.

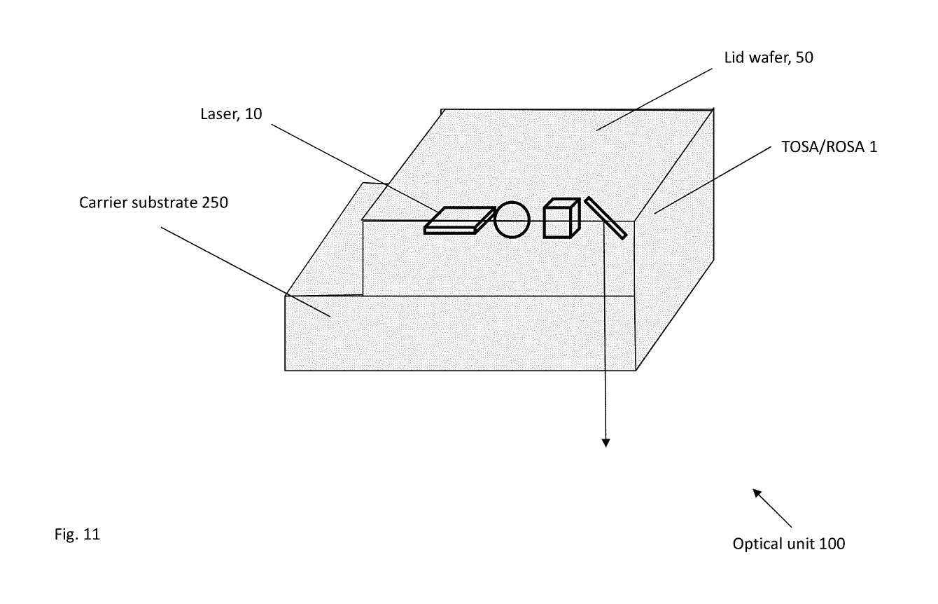

A three-dimensional perspective view of another embodiment of a packaged optical unit 100 is shown in FIG. 11. The optical unit 100 may be a TOSA, a ROSA, or a TOSAROSA, meaning that it may either transmit radiation, receive radiation, or both. The term “optical unit” is meant to broadly encompass all of these possibilities. In the embodiment shown in FIG. 11, the optical source 10 emits radiation which is directed downward and out of the device package as shown in FIG. 11. As described above, the optical radiation device may also include a device which modulates at least one of a frequency and an amplitude, to encode the optical radiation emitted from the light source with an information signal, and at least one optical isolator also disposed within the optical radiation device. The device may or may not also include the plurality of through substrate vias 40 that effectively grounds a metal bonding layer as just described. Accordingly, supporting substrate 250 may be functionally equivalent to substrate 300 in FIG. 10. In the systems and method that follow, the objective may be to optimize the coupling of this encoded optical radiation into a waveguide to carry it to a receiver or detector, or from the optical source.

To this end, the optical unit 100 may in turn be mounted to yet another carrier substrate 25, such as a silicon substrate 25 shown in FIG. 12. The additional silicon substrate 25 may include features that support the optical components of the TOSA and/or the ROSA. Among these features are a plurality of electrical bonding pads 6 and in some embodiments, a waveguide 7 formed in the substrate 25.

One outstanding problem is the alignment of the source (in the case of the TOSA) or the receiver (in the case of the ROSA) to be one or more optical waveguides that transmit the encoded radiation in substrate 25. Described here is a way to actively align the source or the detector to the waveguides 7 built into a carrier substrate 25.

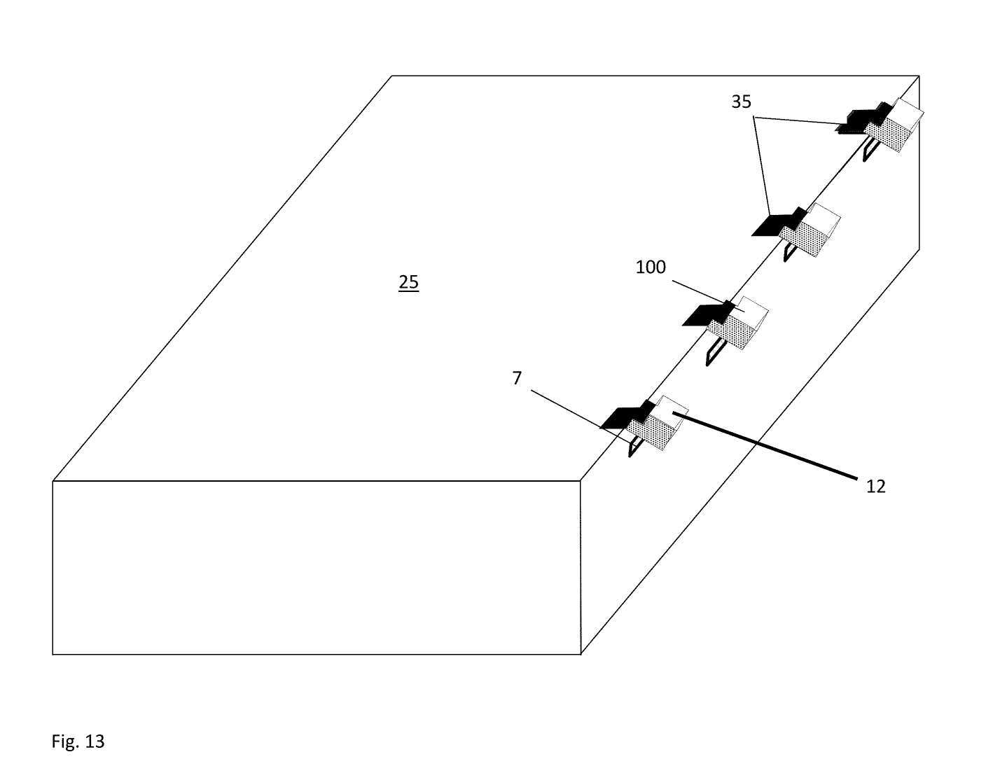

In the following FIGS. 13-19, the following reference numbers refer to the following features:
6 bond pads
7 waveguides
17 cavities
25 carrier substrate
35 flexible electrical connector
1 optical radiation unit or TOSA/ROSA

A plurality of TOSA/ROSAs or other optical radiation unit 100 may be adjusted and mounted on a semiconductor carrier substrate 25 using the following systems and methods. An optical waveguide may have been formed previously in the carrier substrate 25. The systems and methods generally make use of a flexible electrical connector which may be used to provide power to the optical sources 10, while adjusting the orientation of the optical sources 10 with respect to the waveguide 7 in the carrier substrate 25. By having the optical sources 10 mounted on the flexible electrical connector 35, the attitude of the sources 10 may be adjusted to optimize the optical coupling into the waveguide, as described further below.

FIG. 12 shows a plurality of bonding pads 6 disposed on the semiconductor supporting substrate 25. The bonding pads may include a low resistivity deposited metal layer 6 such as gold (Au). Below the gold pad, there may be an additional multilayer structure which may include an adhesion layer, and a diffusion barrier layer in addition to the conductive layer. The adhesion layer may assist in the adherence of the conductive material to the semiconductor substrate 25. The adhesion layer may alternatively be, for example, be titanium (Ti), chrome (Cr) or tantalum (Ta), and may have a thickness of between about 1 to about 50 nm. A barrier layer may also be used, such as platinum, for example, and may have a thickness of about 0.1 μm. The barrier layer may prevent the diffusion of the materials from the adhesion layer into the conductive layer, which may otherwise degrade its conductivity. The conductive layer may be for example gold at the thickness of between 0.2 to 2 μm. The bonding pads 6 may be used to supply a voltage or a current to the flexible electrical connector 35 and thus to the optical source 10.

As shown in FIG. 12, in addition to the bond pads 6, there may also be optical waveguides 7 fabricated into the substrate 25. These waveguides 7 may be used to deliver the radiation from a source to or from, for example, a fiber optic cable. The waveguides 7 may be made by, for example, doping an area of the silicon substrate by ion bombardment, in order to create a region having a different index of refraction than the surrounding material. The walls of the doped region may thereby form a waveguide 7 in the silicon, by reflection of the light by the boundaries between the zones of differing indices. Alternatively, the waveguides 7 may be comprised of a core region, which is composed of SiO2 that has been doped slightly with Ge to increase its refractive index, The cladding region surrounding the core is then composed of undoped SiO2. Again, the interface between these two regions of differing refractive index confines the radiation predominantly to the core region by reflection off of the interface. The methods and devices disclosed here use a flexible connector 35 between the silicon substrate 25 and the TOSAROSA 1 to position the optical TOSAROSA apparatus with a favorable orientation with respect to a waveguide, such as waveguide 7.

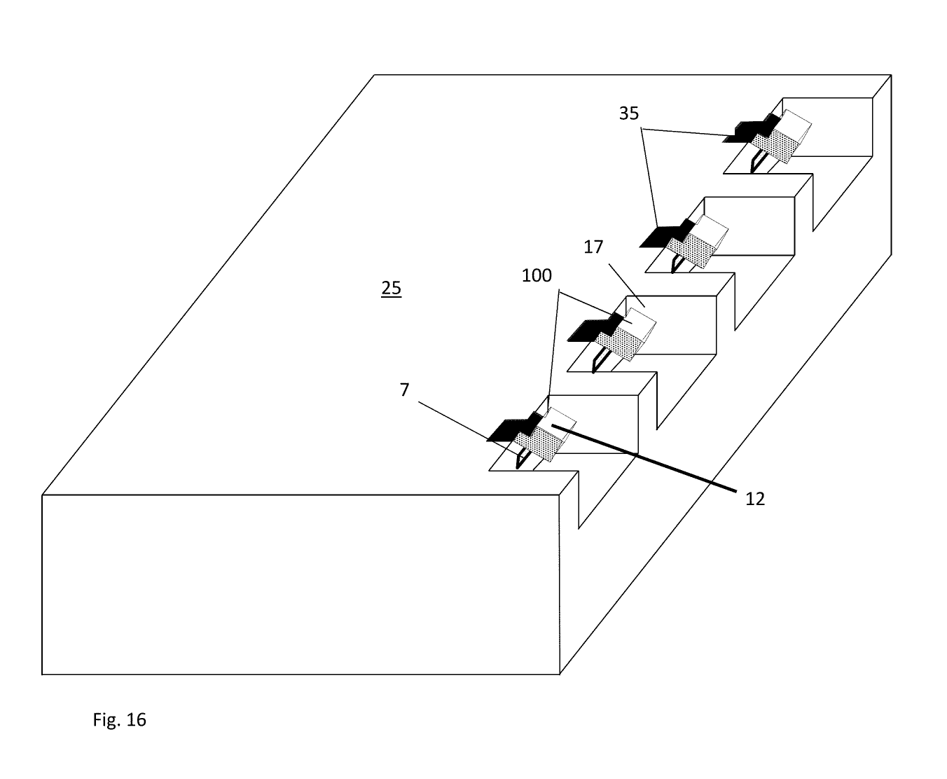

The bonding pads 6 and waveguide 7 may be disposed on an edge (FIG. 12) of a semiconductor carrier substrate 25, or within a pocket 17 (FIG. 16) formed in the substrate 25. Both embodiments are described below.

As shown in FIG. 13, the bonding pads 6 may be coupled to a flexible electrical connector 35, such as a flex cable. The flexible electrical connector 35 may include copper traces encased in a plastic, polyimide structure, which may provide a flexible encasement for metal traces leading to or from the connected device. In this case, the flexible electrical connector 35 may provide power to energize an optical radiation device, such as a solid state laser or TOSA/ROSA 1. Accordingly, the flex cable may be electrically coupled to the bonding pads 6 on one end of the flexible electrical connector 35, and the TOSAROSA 1 on the other end, as shown in FIG. 13.

Instead of a TOSA/ROSA 1, the optical device may be a semiconductor laser, laser diode, photodiode or other chip-based optical device, such as a vertical cavity surface emitting laser (VCSEL). These other optical devices are designated categorically by optical unit 100.

A robot 12 or other sort of articulated mechanism capable of adjusting the attitude of the optical unit 100 may grasp or engage the optical unit 100 and adjust its orientation. The orientation may be adjusted in three dimensions, or pitch, yaw and roll. The robot may engage the optical unit 100 by suction or grasping, for example. The robot may be capable of articulation in at least one dimension. The robot is shown schematically in FIG. 13.

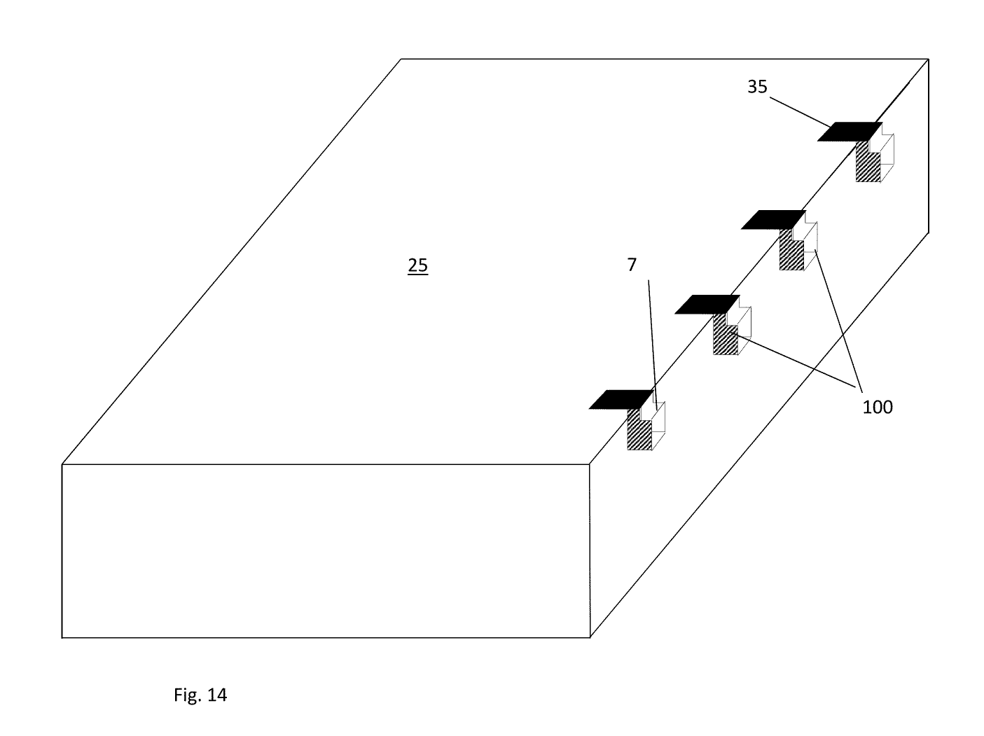

As shown in FIG. 14, the flexible electrical connector 35 may allow the laser to be manipulated while the power is delivered to the optical unit 100. As a result, alignment of the optical apparatus may be conducted to optimize its orientation and radiation coupling into the waveguide 7 with the optical source 10 powered and operating. Although not explicitly shown in the figures, it should be understood that for a ROSA an optical detector may alternatively be placed at the end of waveguide 7, and monitoring the amplitude of the optical radiation inside the waveguide 7, as the position of the optical radiation receiving device (ROSA) 1 is adjusted. When a desirable orientation is achieved, the optical unit 100 may be fixed into place using, for example, a UV curable adhesive. The appearance of the optical unit 100 after fixing in position with the adhesive is shown in FIG. 14.

In a second embodiment, the optical unit 100 may be disposed within a pocket 17 formed in the semiconductor carrier substrate.

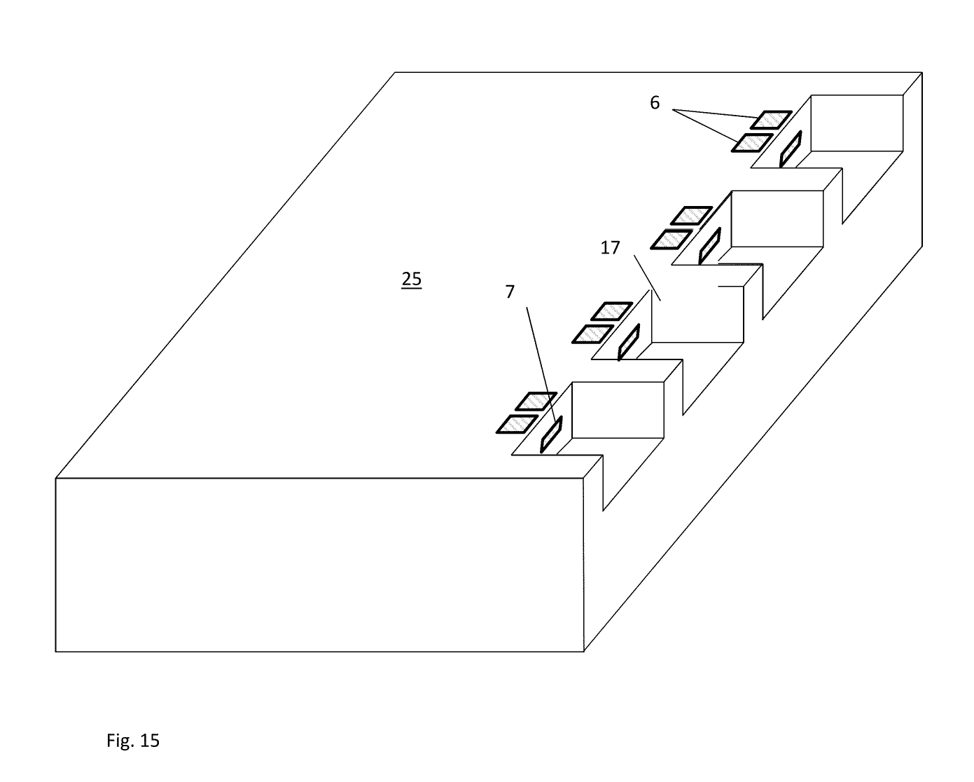

FIG. 15 shows this second embodiment. Once again, a plurality of bonding pads 6 may be disposed on a semiconductor substrate 25 and in the vicinity of a plurality of pockets 17. As before, the bonding pads 6 may also include and adhesion layer, a diffusion barrier layer and a conductive layer. The conductive layer may be gold (Au). The pocket 17 may decrease the overall footprint of the device, which may be advantageous in applications wherein components must be tightly spaced, or space is at a premium and miniaturization is desired. The pockets 17 may also provide coarse alignment of the optical devices such that there is finite, albeit suboptimal, optical power launched into the waveguide before the robot performs the active alignment procedure. This can greatly facilitate the initiation of an active alignment algorithm.

As shown in FIG. 15, in addition to the bond pads 6, there may also be optical waveguides 7 fabricated into the substrate 25. These waveguides 7 may be used to deliver the radiation from a source to, for example, a fiber optic cable. As before, the waveguides may be made by, for example, doping an area of the silicon substrate by ion bombardment, in order to create a region having a different index of refraction.

FIG. 16 shows the substrate 25 with a plurality of optical units 1 coupled to the flexible connectors 35. As shown in FIG. 16, the bonding pads 6 may be coupled to a flexible electrical connector, such as a flex cable 35. As before, the flexible electrical connector 35 may include copper traces encased in a plastic, polyimide structure, may provide a flexible encasement for metal traces leading to or from the connected device. In this case, the flexible electrical connector 35 may provide power to energize the solid state laser. Accordingly, the flexible electrical connector 35 may be electrically coupled to the bonding pads 6 on one end of the flexible electrical connector 35, and to the optical device 1 on the other end.

As before, a robot 12 or other sort of articulated mechanism capable of adjusting the attitude of the optical unit 100 may grasp or engage the optical unit 100 and adjust its orientation. The orientation may be adjusted in three dimensions, or pitch, yaw and roll.

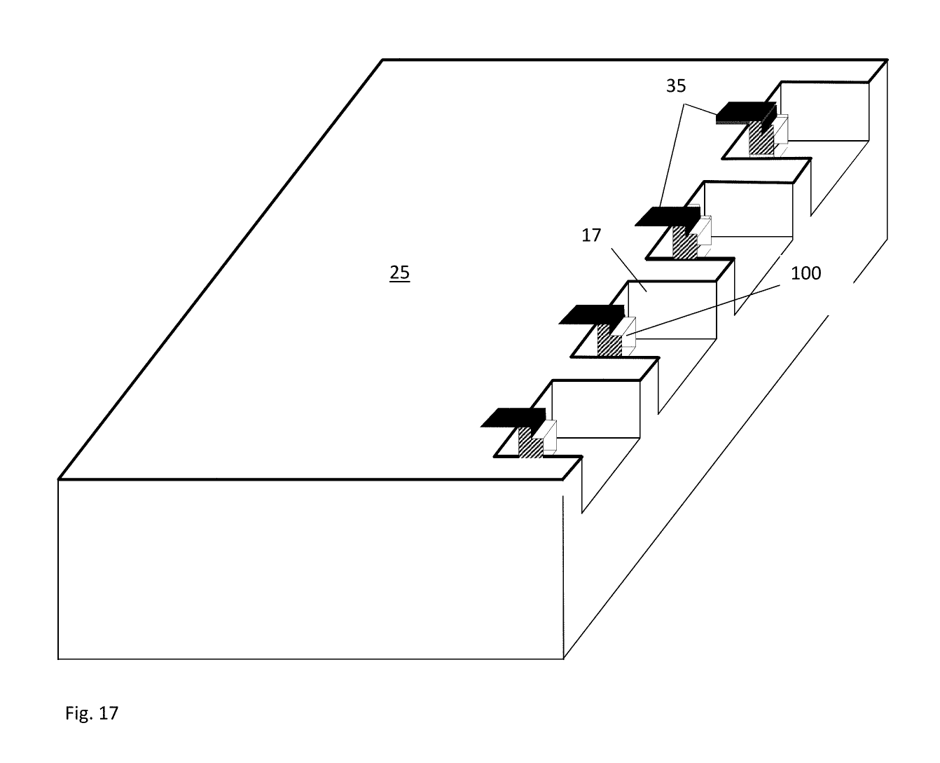

As shown in FIG. 16, the flexible connector may allow the laser to be manipulated while the power is delivered to the optical apparatus 1. As a result, alignment of the optical apparatus may be conducted to optimize its orientation. When a desirable orientation is achieved, the optical apparatus 1 may be fixed into place using, for example, a UV curable adhesive. Although not explicitly shown in the figures, it should be understood that an optical detector may be placed at the end of waveguide 7 in the case of receiver, and monitoring the amplitude of the optical radiation inside the waveguide 7, as the position of the optical unit 1 is adjusted. When a desired signal level is achieved, the optical radiation device may be fastened to the carrier substrate 25 using a quick curing adhesive, for example. The condition of the carrier substrate 25 with affixed optical unit 100 is shown in FIG. 17.

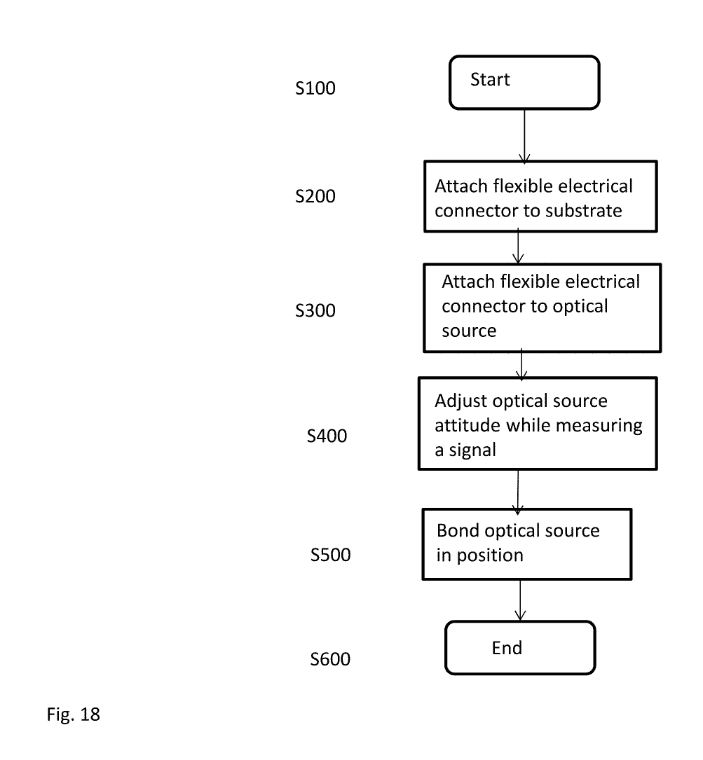

The method is illustrated in FIG. 18. The method begins in step S100. In step S200, the flexible electrical connector may be attached to the substrate. In step S300, the flexible electrical connector may be coupled to the optical source. In step S400, the position or attitude of the optical source may be adjusted robotically, while a signal associated with the optical source is monitored. In step S500, the optical source is bonded to the substrate in the adjusted position. The method may end in step S600.

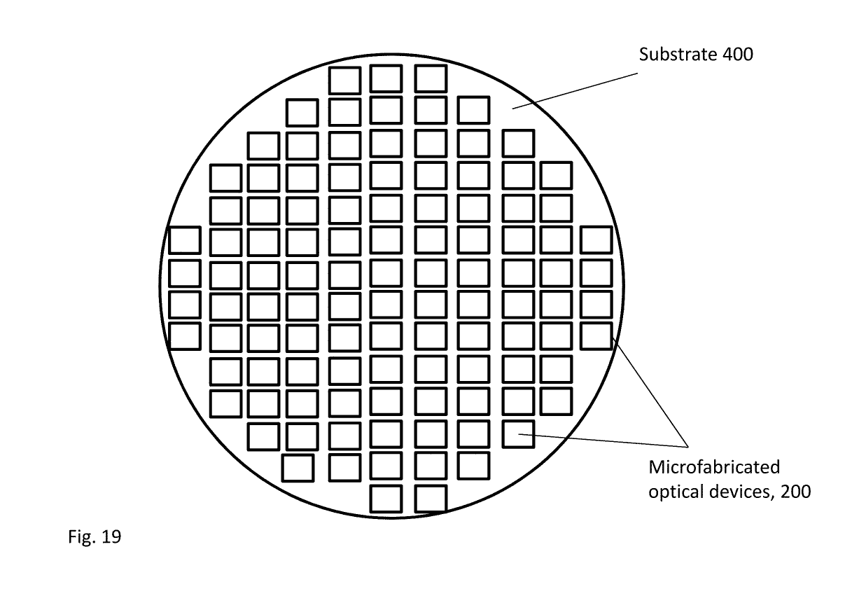

FIG. 19 is a simplified plan view of a fabrication substrate during processing in a manufacturing environment in the fabrication of TOSAROSA 1 or TOSAROSE 2. As was described previously, the manufacturing method may be capable of fabricating a large number of like devices 200 on a single fabrication substrate 400. These devices may each be microfabricated optical apparatuses 200. This fabrication substrate 400 may be bonded to a lid substrate (not shown) with cavities and perhaps other structures previously formed therein, and registered with the optical apparatuses 200, to form a two-substrate assembly. The individual devices may they be singulated by sawing, dicing or grinding.

The flexible electrical connector 35 or flexible cable may be similar to a “flex cable”, which is a flat, planar sheet of plastic such as polyimide, in which a plurality of copper conductors is encased. The insulating plastic material may be polyimide, polyurethane or a thermoplastic polyester elastomer, for example. The embedded conductors are typically copper, but may be some other malleable metal. With the flexible electrical connector 35 described here, power may be delivered to the laser while still allowing it to move with respect to the waveguide 7. This may allow active alignment of the optical source 10.

More broadly, however, the flexible electrical connector 35 may be any flexible structure in which a plurality of conductors is embedded. A flex cable may be an example of a flexible electrical connector 35. The conductors may be electrically and mechanically connected to a source of power and/or voltage on one proximate end. In another area, such as at the other distal end, a microfabricated device may be mounted onto the flexible electrical connector. Accordingly, we describe here an application wherein a lithographically manufactured device, such as a MEMS device, a laser or an integrated circuit (IC) is mounted on a flexible or semi-rigid surface, rather than the usual rigid, semiconductor surface. The term “flexible” may be understood to mean that the microfabricated device which is mounted to the flexible electrical connector, is capable of moving relative to the source of power and/or voltage at the proximate end.

The flexible connector may be relatively small, on the order of a few hundred microns across, and may, itself, be made using microfabrication techniques. For example, a patternable, insulating material such as a photoresist may be inlaid with a copper conductor through a lithographic mask. The MEMS or integrated circuit (IC) may be bump bonded or wire bonded to this microfabricated flex cable. Flexible, thick film photoresists are known, such as a novolac resin, a quinone diazide photosensitizer, and a propylene glycol alkylether acetate are improved by the addition of a plasticizer such as polypropylene acetal resin according to U.S. Pat. No. 5,066,561. Such microfabricated flexible connectors may be less than about 500 microns, or at least less than about 1 mm, in their largest cross sectional dimension, and/or less than about 2 mm in any dimension.

Accordingly, disclosed here is a microfabricated optical apparatus fabricated on a semiconductor substrate, which includes an optical radiation device, at least one bonding pad that handles at least one of a signal and a voltage to the optical radiation device, wherein the at least one bonding pad is formed on the semiconductor substrate, and a flexible electrical connector that electrically couples the optical radiation device to the bonding pad, allowing the optical radiation device to be moved with respect to the substrate while the optical radiation device is energized. The device may further include an optical source driven by a first signal with a characteristic frequency of □, wherein the optical source generates optical radiation, an optical detector which generates a second signal based on an amount of optical radiation striking the optical detector, wherein the first and second signals are delivered to the optical source or taken from the optical detector by a plurality of through silicon vias (TSV) which extend through a thickness of the substrate, and a metallic layer deposited on at least one side of the substrate and covering at least one half of area of the surface of the substrate, and electrically coupled to a ground plane on the obverse side of the substrate by the plurality of through substrate vias (TSVs), wherein the through wafer vias are disposed at intervals of between about c/(□*□) and c/(10*□*□), where c is the speed of light and epsilon is the dielectric constant of the substrate.

The microfabricated structure may further include at least one waveguide formed in the semiconductor substrate, wherein radiation in the waveguide is optically coupled to the optical radiation device. The optical radiation device may be at least one of an emitter and a detector. The optical radiation device may alternatively be at least one of a light emitting diode, a laser diode, an edge emitting laser diode, a laser diode. and a vertical cavity surface emitting laser (VCSEL). The flexible electrical connector may supply power, ground and a modulated signal encoding information to the optical radiation device. Radiation from the optical radiation device may be optically coupled to the waveguide formed in the semiconductor substrate. The TSVs may be located between an optical source and an optical detector, and in regions where a lid wafer is bonded to the substrate.

The microfabricated optical apparatus may further comprise a device which modulates at least one of a frequency and an amplitude, to encode the optical radiation emitted from the light source with an information signal, and at least one optical isolator also disposed within the optical radiation device. The optical radiation device may be mounted on either an edge of the semiconductor substrate or in a pocket formed in the edge of the semiconductor substrate. The flexible electrical connector may be less than about 500 microns in its largest cross sectional dimension, and largest characteristic dimension (length) of less that about 5 mm. The apparatus may perform at least one of Coarse Wavelength Divisional Multiplexing (CWDM) and Dense Wavelength Divisional Multiplexing (DWDM).

Disclosed here as well is a method for mounting an microfabricated optical radiation device onto a semiconductor substrate, which may include coupling one end a flexible electrical connector to the semiconductor substrate, coupling the other end of the flexible electrical connector to the microfabricated optical radiation device, adjusting the position of the optical radiation device by measuring an change in a signal amplitude, and bonding the microfabricated optical radiation device to the semiconductor substrate. The method may further include providing an optical apparatus which supports signals having a characteristic wavelength of □ corresponding to a characteristic frequency of □, disposing an optical source driven by a first signal with a characteristic frequency of □ on a substrate, wherein the optical source generates optical radiation, disposing an optical detector on the substrate, which generates a second signal based on an amount of optical radiation striking the optical detector, wherein the first and second signals are delivered to the optical source or taken from the optical detector by a plurality of through silicon vias (TSV) which extend through a thickness of the substrate

The method may additionally include forming a plurality of through wafer vias extending through the substrate, that define a conductive path between a ground plane on one side of the substrate and a metal material on the obverse side of the substrate, wherein the through substrate vias are disposed at intervals of between about c/(v*ϵ) and c/(10*v*ϵ), where c is the speed of light and epsilon is the dielectric constant of the substrate, and wherein the metal material covers at least one half of the exposed area of the surface of the substrate, forming the ground plane which is held at ground potential relative to the wafer bonding material, and electrically coupling the metal material to the ground plane by the plurality of through substrate vias (TSVs). The method may further comprise forming at least one waveguide in the semiconductor substrate. Radiation in the waveguide may be optically coupled to the optical radiation device. The optical radiation device may be at least one of an emitter and a detector. The optical radiation device may be at least one of a light emitting diode, a laser diode, an edge emitting laser diode, a laser diode. and a vertical cavity surface emitting laser (VCSEL). The flexible electrical connector may be a microfabricated structure, wherein a plurality of conductors is deposited lithographically on an insulating plastic material.

In this method, the flexible electrical connector may supply power, ground and a modulated signal encoding information to the VCSEL. The method may further comprise coupling radiation from the optical radiation device into the waveguide formed in the semiconductor substrate.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Furthermore, details related to the specific methods, dimensions, materials uses, shapes, fabrication techniques, etc. are intended to be illustrative only, and the invention is not limited to such embodiments. Descriptors such as top, bottom, left, right, back front, etc. are arbitrary, as it should be understood that the systems and methods may be performed in any orientation. Accordingly, the exemplary implementations set forth above, are intended to be illustrative, not limiting.

What is claimed is:

1. A microfabricated optical apparatus fabricated on a semiconductor substrate, comprising:
an optical radiation device;
at least one bonding pad that handles at least one of a signal and a voltage to the optical radiation device, wherein the at least one bonding pad is formed on the semiconductor substrate; and
a flexible electrical connector that electrically couples the optical radiation device to the bonding pad, allowing the optical radiation device to be moved with respect to the substrate while the optical radiation device is energized, so as to improve the coupling of the optical radiation into a waveguide.

2. The microfabricated optical apparatus of claim 1, further comprising:
an optical source driven by a first signal with a characteristic frequency of □, wherein the optical source generates optical radiation;
an optical detector which generates a second signal based on an amount of optical radiation striking the optical detector, wherein the first and second signals are delivered to the optical source or taken from the optical detector by a plurality of through silicon vias (TSV) which extend through a thickness of the substrate; and
a metallic layer deposited on at least one side of the substrate and covering at least one half of area of the surface of the substrate, and electrically coupled to a ground plane on the obverse side of the substrate by the plurality of through substrate vias (TSVs), wherein the through wafer vias are disposed at intervals of between about c/(□* □) and c/(10*□*□), where c is the speed of light and epsilon is the dielectric constant of the substrate.

3. The microfabricated optical apparatus of claim 1, wherein the waveguide is formed in the semiconductor substrate.

4. The microfabricated optical apparatus of claim 3, wherein radiation in the waveguide is optically coupled to the optical radiation device.

5. The microfabricated optical apparatus of claim 1, wherein the optical radiation device is at least one of an emitter and a detector.

6. The microfabricated optical apparatus of claim 5, wherein the optical radiation device is at least one of a light emitting diode, a laser diode, an edge emitting laser diode, a laser diode. and a vertical cavity surface emitting laser (VCSEL).

7. The microfabricated optical apparatus of claim 6, wherein the flexible electrical connector supplies power, ground and a modulated signal encoding information to the optical radiation device.

8. The microfabricated optical apparatus of claim 7, wherein radiation from the optical radiation device is optically coupled to the waveguide formed in the semiconductor substrate.

9. The microfabricated optical apparatus of claim 2, wherein the TSVs are located between an optical source and an optical detector, and in regions where a lid wafer is bonded to the substrate.

10. The microfabricated optical apparatus of claim 1, further comprising:
a device which modulates at least one of a frequency and an amplitude, to encode the optical radiation emitted from the light source with an information signal; and
at least one optical isolator also disposed within the optical radiation device.

11. The microfabricated optical apparatus of claim 1, wherein the optical radiation device is mounted on either an edge of the semiconductor substrate or in a pocket formed in the edge of the semiconductor substrate.

12. The microfabricated optical apparatus of claim 1, wherein the flexible electrical connector is less than about 500 microns in its largest cross sectional dimension.

13. A method for mounting an microfabricated optical radiation device onto a semiconductor substrate, comprising:
coupling one end a flexible electrical connector to the semiconductor substrate;
coupling the other end of the flexible electrical connector to the microfabricated optical radiation device;
adjusting the position of the optical radiation device by measuring an change in a signal amplitude;
bonding the microfabricated optical radiation device to the semiconductor substrate.

14. The method of claim 13, further comprising providing an optical apparatus which supports signals having a characteristic wavelength of □ corresponding to a characteristic frequency of □;
disposing an optical source driven by a first signal with a characteristic frequency of □ on a substrate, wherein the optical source generates optical radiation;
disposing an optical detector on the substrate, which generates a second signal based on an amount of optical radiation striking the optical detector, wherein the first and second signals are delivered to the optical source or taken from the optical detector by a plurality of through silicon vias (TSV) which extend through a thickness of the substrate;
forming a plurality of through wafer vias extending through the substrate, that define a conductive path between a ground plane on one side of the substrate and a metal material on the obverse side of the substrate, wherein the through substrate vias are disposed at intervals of between about c/(□*□) and c/(10*□*□), where c is the speed of light and epsilon is the dielectric constant of the substrate, and wherein the metal material covers at least one half of the exposed area of the surface of the substrate;
forming the ground plane which is held at ground potential relative to the wafer bonding material; and
and electrically coupling the metal material to the ground plane by the plurality of through substrate vias (TSVs).

15. The method of claim 13, further comprising:
forming at least one waveguide in the semiconductor substrate.

16. The method of claim 13, wherein radiation in the waveguide is optically coupled to the optical radiation device.

17. The method of claim 13, wherein the optical radiation device is at least one of an emitter and a detector.

18. The method of claim 13, wherein the optical radiation device is at least one of a light emitting diode, a laser diode, an edge emitting laser diode, a laser diode. and a vertical cavity surface emitting laser (VCSEL).

19. The method of claim 13, wherein the flexible electrical connector is a microfabricated structure, wherein a plurality of conductors is deposited lithographically on an insulating plastic material.

20. The method of claim 13, further comprising:
coupling radiation from the optical radiation device into the waveguide formed in the semiconductor substrate.
